(19) United States
(12) Patent Application Publication
(10) Pub. No.: US 2026/0237434 A1
(43) Pub. Date: Aug. 13, 2026

(54) THREE-DIMENSIONAL MEMORY DEVICE CONTAINING LATERALLY-UNDULATING LATERAL ISOLATION TRENCHES AND METHOD OF MAKING THEREOF USING AT LEAST THREE ROWS OF ISOLATION OPENINGS

(71) Applicant: Sandisk Technologies, Inc., Milpitas, CA (US)

(72) Inventors: Bing ZHOU, San Jose, CA (US); Koichi MATSUNO, Fremont, CA (US); Senaka KANAKAMEDALA, San Jose, CA (US)

(21) Appl. No.: 19/050,462

(22) Filed: Feb. 11, 2025

(51) Int. Cl. G11C 16/04; H10B 41/10; H10B 41/27; H10B 41/35; H10B 43/10; H10B 43/27; H10B 43/35

(52) U.S. Cl. CPC G11C 16/0483; H10B 41/10; H10B 41/27; H10B 41/35; H10B 43/10; H10B 43/27; H10B 43/35

(57) ABSTRACT

A method includes forming a vertically alternating sequence of continuous insulating layers and continuous sacrificial material layers, forming memory openings and at least three adjacent rows of isolation openings, forming sacrificial isolation opening fill structures in the at least three rows of isolation openings, forming memory opening fill structures in the memory openings, forming isolation cavities by removing a first subset of the sacrificial isolation opening fill structures from a middle row of the isolation openings without removing a second subset of the sacrificial isolation opening fill structures located in peripheral rows of the isolation openings, forming laterally-undulating lateral isolation trenches through the vertically alternating sequence by performing at least one isotropic etch process that etches materials of the vertically alternating sequence around the first subset of isolation openings, and replacing the sacrificial material layers in the multiple alternating stacks with electrically conductive layers.

### FIELD

The present disclosure relates generally to the field of semiconductor devices, and particularly to a three-dimensional memory device containing laterally-undulating lateral isolation trenches and method of making thereof using at least three rows of isolation openings.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure includes alternating stacks of insulating layers and electrically conductive layers, wherein each of the alternating stacks laterally extends along a first horizontal direction, wherein the alternating stacks are laterally spaced apart from each other along a second horizontal direction by lateral isolation trench fill structures that laterally extend along the first horizontal direction; memory openings vertically extending through a respective one of the alternating stacks; and memory opening fill structures each located in a respective one of the memory openings and comprising a respective vertical stack of memory elements located at levels of the electrically conductive layers and a respective vertical semiconductor channel, wherein the memory opening fill structures are arranged in rows each laterally extending along the first horizontal direction with a memory opening periodicity having a first pitch, wherein: each of the lateral isolation trench fill structures comprises a respective pair of lengthwise sidewalls, wherein each of the lengthwise sidewalls laterally extends generally along the first horizontal direction and comprises respective lateral undulations along a second horizontal direction that is perpendicular to the first horizontal direction, the respective lateral undulations having an undulation periodicity that equals the first pitch; and geometrical centers of the memory opening fill structures and centers of curvature of the lateral undulations of the lateral isolation trench fill structures are located at lattice points of a two-dimensional periodic array in a horizontal cross-sectional view.

According to another aspect of the present disclosure, a semiconductor structure comprises: alternating stacks of insulating layers and electrically conductive layers, wherein each of the alternating stacks laterally extends along a first horizontal direction, wherein the alternating stacks are laterally spaced apart from each other along a second horizontal direction by lateral isolation trench fill structures that laterally extend along the first horizontal direction; memory openings vertically extending through a respective one of the alternating stacks; and memory opening fill structures each located in a respective one of the memory openings and comprising a respective vertical stack of memory elements located at levels of the electrically conductive layers and a respective vertical semiconductor channel, wherein the memory opening fill structures are arranged in rows each laterally extending along the first horizontal direction with a memory opening periodicity having a first pitch, wherein: each of the lateral isolation trench fill structures comprises a respective pair of lengthwise sidewalls, wherein each of the lengthwise sidewalls laterally extends generally along the first horizontal direction and comprises respective lateral undulations along a second horizontal direction that is perpendicular to the first horizontal direction, the respective lateral undulations having an undulation periodicity that equals the first pitch; and the respective lateral undulations comprise vertically-straight and horizontally oval-arc-shaped surface segment in direct contact with vertically-straight and horizontally-concave surface segments of electrically conductive layers of a respective alternating stack.

According to yet another aspect of the present disclosure, a method of forming a semiconductor structure comprises forming a vertically alternating sequence of continuous insulating layers and continuous sacrificial material layers; forming memory openings and at least three adjacent rows of isolation openings though the vertically alternating sequence; forming sacrificial isolation opening fill structures in the at least three rows of isolation openings; forming memory opening fill structures in the memory openings, wherein each of the memory opening fill structures comprises a respective vertical stack of memory elements and a vertical semiconductor channel; forming isolation cavities by removing a first subset of the sacrificial isolation opening fill structures from a middle row of the isolation openings without removing a second subset of the sacrificial isolation opening fill structures located in peripheral rows of the isolation openings; forming laterally-undulating lateral isolation trenches through the vertically alternating sequence by performing at least one isotropic etch process that etches materials of the vertically alternating sequence around the first subset of isolation openings to divide the vertically alternating sequence into multiple alternating stacks of respective insulating layers and respective sacrificial material layers that are laterally spaced apart by the laterally-undulating lateral isolation trenches; and replacing the sacrificial material layers in the multiple alternating stacks with electrically conductive layers.

### BRIEF DESCRIPTION OF THE DRAWINGS

Within each of FIG. 1A-1C, 4A-11C, 13A-14C, 19A-22C, 25A-25C, and 29A-29C, each figure is labeled with a combination of a figure numeral and an alphabetical suffix. Each set of figures with the same figure numeral corresponds to views for a first exemplary structure at a same processing step. Each figure with the alphabetical suffix “B” is a top-down view of the first exemplary structure. Each figure with the alphabetical suffix “A” is a vertical cross-sectional view along a vertical plane A-A′ in the figure with the same figure numeral and the alphabetical suffix “B.” Each figure with the alphabetical suffix “C” is a vertical cross-sectional view along a vertical plane C-C′ in the figure with the same figure numeral and the alphabetical suffix “B.”

FIG. 1A-1C are various view of a first exemplary structure for forming a semiconductor die after formation of semiconductor devices, lower-level metal interconnect structures, lower-level dielectric material layers, a vertically alternating sequence of first-tier continuous insulating layers and first-tier continuous sacrificial material layers, and first-tier stepped cavities according to an embodiment of the present disclosure.

FIG. 2A-2C are sequential vertical cross-sectional views of a region of the first exemplary structure during thickening of physically-exposed portions of the first-tier sacrificial material layers according to an embodiment of the present disclosure.

FIG. 3A-3E are sequential vertical cross-sectional views of a region of the first exemplary structure during a sequence of processing steps that may be employed to locally thicken the physically-exposed portions of the first-tier sacrificial material layers according to an embodiment of the present disclosure.

FIG. 4A-4C are various view of the first exemplary structure after local thickening of the first-tier sacrificial material layers and formation of first-tier retro-stepped dielectric material portions according to an embodiment of the present disclosure.

FIG. 5A-5C are various views of the first exemplary structure after formation of various first-tier openings and various first-tier sacrificial opening fill structures according to an embodiment of the present disclosure. FIG. 5D is a horizontal cross-sectional view of region D in FIG. 5B at a level of a third-tier continuous sacrificial material layer.

FIG. 6A-6C are various views of the first exemplary structure after formation of a vertically alternating sequence of second-tier continuous insulating layers and second-tier continuous sacrificial material layers, second-tier retro-stepped dielectric material portions, and various second-tier openings and various second-tier sacrificial opening fill structures according to an embodiment of the present disclosure.

FIG. 7A-7D are various views of the first exemplary structure after formation of a vertically alternating sequence of third-tier continuous insulating layers and third-tier continuous sacrificial material layers, third-tier retro-stepped dielectric material portions, and various third-tier openings and various third-tier sacrificial opening fill structures according to an embodiment of the present disclosure. FIG. 7D is a horizontal cross-sectional view of region D in FIG. 7B at a level of a third-tier continuous sacrificial material layer.

FIG. 8A-8D are various views of the first exemplary structure after formation of memory openings, support openings, isolation openings, and contact openings according to an embodiment of the present disclosure. FIG. 8D is a horizontal cross-sectional view of region D in FIG. 8B at a level of a third-tier continuous sacrificial material layer.

FIG. 9A-9C are various views of the first exemplary structure after formation of a patterned mask layer according to an embodiment of the present disclosure.

FIG. 10A-10C are various views of the first exemplary structure after formation of sacrificial isolation opening fill structures and sacrificial contact opening fill structures according to an embodiment of the present disclosure.

FIG. 11A-11C are various views of the first exemplary structure after formation of cavities in memory openings and support openings according to an embodiment of the present disclosure.

FIG. 12A-12F illustrate sequential vertical cross-sectional views of a memory opening during formation of a memory opening fill structure according to an embodiment of the present disclosure.

FIG. 13A-13D are various views of the first exemplary structure after formation of memory opening fill structures according to an embodiment of the present disclosure. FIG. 13D is a horizontal cross-sectional view of region D in FIG. 13B at a level of a third-tier continuous sacrificial material layer.

FIG. 14A-14C are various views of the first exemplary structure after formation of a first photoresist layer including openings in which the sacrificial contact opening fill structures are exposed according to an embodiment of the present disclosure.

FIG. 15 is a vertical cross-sectional view of the first exemplary structure after formation of contact via cavities according to an embodiment of the present disclosure.

FIG. 16 is a vertical cross-sectional view of the first exemplary structure after formation of annular lateral recesses around the contact via cavities according to an embodiment of the present disclosure.

FIG. 17 is a vertical cross-sectional view of the first exemplary structure after removal of the first photoresist layer and formation of annular dielectric spacers in a subset of the annular lateral recesses according to an embodiment of the present disclosure.

FIG. 18 is a vertical cross-sectional view of the first exemplary structure after formation of sacrificial through-via structures according to an embodiment of the present disclosure.

FIG. 19A-19D are various views of the first exemplary structure after formation and patterning of a second photoresist layer and after removal of a first subset of the sacrificial isolation opening fill structures according to an embodiment of the present disclosure. FIG. 19D is a horizontal cross-sectional view of region D in FIG. 17B at a level of a third-tier continuous sacrificial material layer.

FIG. 20A-20E are various views of the first exemplary structure after formation of lateral isolation trenches according to an embodiment of the present disclosure. FIG. 20D is a horizontal cross-sectional view of the first exemplary structure along the horizontal plane D-D′ of FIGS. 20A and 20C. FIG. 20E is a horizontal cross-sectional view of region E in FIG. 20B at a level of a third-tier continuous sacrificial material layer.

FIG. 21A-21E are various views of the first exemplary structure after removal of a second subset of the sacrificial isolation opening fill structures according to an embodiment of the present disclosure. FIG. 21D is a horizontal cross-sectional view of the first exemplary structure along the horizontal plane D-D′ of FIGS. 21A and 21C. FIG. 21E is a horizontal cross-sectional view of region E in FIG. 21B at a level of a third-tier continuous sacrificial material layer.

FIG. 22A-22C are various views of the first exemplary structure after removal of the second photoresist layer according to an embodiment of the present disclosure.

FIG. 23 is a vertical cross-sectional view of the first exemplary structure after formation of laterally-extending cavities according to an embodiment of the present disclosure.

FIG. 24 is a vertical cross-sectional view of the first exemplary structure after formation of electrically conductive layers according to an embodiment of the present disclosure.

FIG. 25A-25D are various views of the first exemplary structure after formation of lateral isolation trench fill structures according to an embodiment of the present disclosure. FIG. 25D is a horizontal cross-sectional view of region D in FIG. 25B at a level of a third electrically conductive layer.

FIG. 26 is a vertical cross-sectional view of the first exemplary structure after formation of connection via cavities according to an embodiment of the present disclosure.

FIG. 27 is a vertical cross-sectional view of the first exemplary structure after formation of through-via contact cavities according to an embodiment of the present disclosure.

FIG. 28 is a vertical cross-sectional view of the first exemplary structure after formation of through-via contact structures according to an embodiment of the present disclosure.

FIG. 29A-29C are various view of the first exemplary structure after formation of drain contact via structures according to an embodiment of the present disclosure.

FIG. 30A-30F are various horizontal cross-sectional views of a second exemplary structure at a level of a third sacrificial material layer or a third electrically conductive layer according to an embodiment of the present disclosure.

FIG. 31A-31C are various horizontal cross-sectional views of a third exemplary structure at a level of a third sacrificial material layer or a third electrically conductive layer according to an embodiment of the present disclosure.

### DETAILED DESCRIPTION

As discussed above, the embodiments of the present disclosure are directed to a three-dimensional memory array containing laterally-undulating lateral isolation trenches and method of making thereof using at least three rows of isolation openings, the various aspects of which are now described in detail.

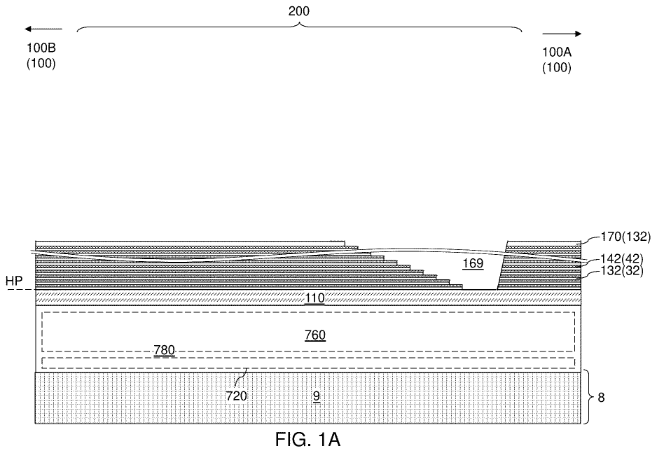

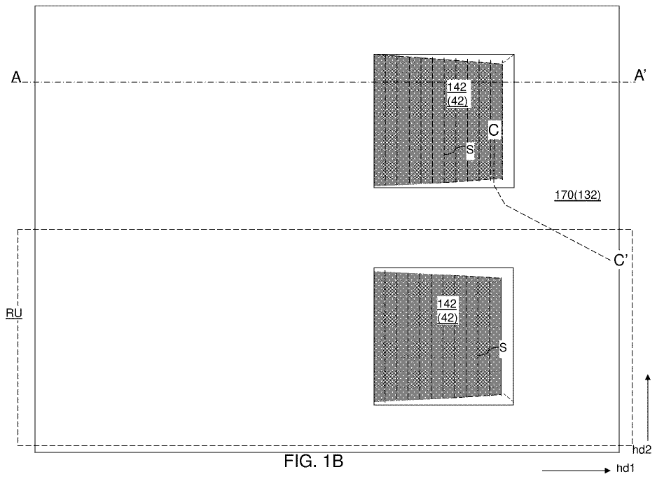

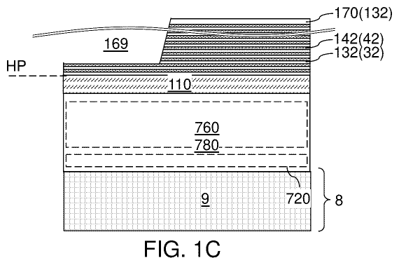

Referring to FIG. 1A-1C, a first exemplary structure according to an embodiment of the present disclosure is illustrated after formation of optional semiconductor devices, optional lower level dielectric layers, optional lower metal interconnect structures, a semiconductor material layer 110, and a first-tier vertically alternating sequence (132, 142) of first continuous insulating layers 132 and first continuous sacrificial material layers 142, a first insulating cap layer 170, and first-tier stepped cavities 169 containing stepped surfaces (i.e., a staircase region) according to an embodiment of the present disclosure.

The first exemplary structure comprises a substrate 8 including a substrate semiconductor layer 9 (e.g., doped well in the silicon wafer or a silicon layer located on the substrate 8). Semiconductor devices 720 can be formed on the substrate semiconductor layer 9. In one embodiment, the semiconductor devices 720 may comprise a peripheral circuit configured to control operation of a three-dimensional memory device to be subsequently formed. Lower-level dielectric material layer 760 embedding lower-level metal interconnect structures 780 (not individually shown) may be formed over the semiconductor devices 720. In some embodiments, the lower-level metal interconnect structures 780 may comprise metal pads 788 configured to be subsequently connected to connection via structures and electrically connected to a respective node of the semiconductor devices 720 through a subset of the lower-level metal interconnect structures 780.

In an alternative embodiment, the peripheral circuit containing the semiconductor devices 720 may be formed on a separate substrate that is part of a logic die. The logic may be subsequently bonded to a memory die containing a three-dimensional memory device formed over the substrate 8.

A semiconductor material layer 110 can be formed over the lower-level dielectric material layers 760 by deposition of a semiconductor material or by transfer of the semiconductor material layer 110 employing a carrier substrate (not shown). The semiconductor material layer 110 may comprise a polycrystalline semiconductor material layer or a single crystalline semiconductor material layer. The thickness of the semiconductor material layer 110 may be in a range from 100 nm to 2,000 nm, although lesser and greater thicknesses may also be employed. A top surface of the semiconductor material layer 110 may be provided within a horizontal plane HP.

A first vertically alternating sequence of first-tier insulating layers 132 and first-tier sacrificial material layers 142 can be formed over the semiconductor material layer 110. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. The first vertically alternating sequence of first-tier insulating layers 132 and first-tier sacrificial material layers 142 is also referred to as a first-tier alternating stack (132, 142). Generally, the first-tier insulating layers 132 are a first subset of insulating layers 32 to be formed in the first exemplary structure, and the first-tier sacrificial material layers 142 are a first subset of sacrificial material layers 42 to be formed in the first exemplary structure. As such, the first-tier alternating stack (132, 142) is one of alternating stacks (32, 42) that are formed in the first exemplary structure.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the semiconductor material layer 110, and may have a uniform thickness throughout. Each of the first-tier sacrificial material layers 142 includes a sacrificial material (which may comprise a dielectric material), and continuously extends over the entire area of the semiconductor material layer 110, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide. The topmost one of the first-tier insulating layers 132 is herein referred as a first-tier insulating cap layer 170.

The second material of the first-tier sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks over a substrate. Each of the unit layer stacks comprises a first-tier insulating layer (such as a first-tier insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted. The first exemplary structure comprises a pair of memory array regions (100A, 100B) and a contact region 200 located between the pair of memory array regions (100A, 100B). The pair of memory regions (100A, 100B) may comprise a first memory array region 100A and a second memory array region 100B.

First-tier stepped cavities 169 can be formed through the first-tier alternating stack (132, 142). The first-tier stepped cavities 169 can be formed in a periodic pattern within the area of the contact region 200. For example, the first memory array region 100A and the second memory array region 100B may be laterally spaced apart from each other along a first horizontal direction (e.g., word line direction) hd1. The contact region 200 may be located between the first memory array region 100A and the second memory array region 100B. The first-tier stepped cavities 169 may be laterally spaced apart along a second horizontal direction (e.g., bit line direction) hd2 that is perpendicular to the first horizontal direction hd1. In one embodiment, the first-tier stepped cavities 169 may be formed as a periodic one-dimensional array of first-tier stepped cavities 169 arranged along the second horizontal direction hd2. In this case, the pattern of the first-tier stepped cavities 169 may be a periodic repetition of a unit pattern located within a repetition unit RU.

In the illustrated example, each repetition unit RU laterally extends along the first horizontal direction hd1 through the entirety of the first memory array region 100A (of which only an edge portion is illustrated), the entirety of the second memory array region 100B (of which only an edge portion is illustrated), and the contact region 200. The width of the repetition unit RU may be the same as the periodicity of the periodic one-dimensional array of first-tier stepped cavities 169. Generally, each repetition unit RU may be defined as a rectangular area having a lengthwise edge that is parallel to the first horizontal direction hd1 at any location. In the illustrated example, each repetition unit RU is defined to have lengthwise edges that coincide with two mirror symmetry vertical planes for a neighboring pair of first-tier stepped cavities 169 along the first horizontal direction hd1. In this case, each of the two mirror symmetry vertical planes extends through a respective one of the first-tier stepped cavities 169. The pattern in the repetition unit RU may be repeated along the second horizontal direction hd2.

In one embodiment, first-tier stepped surfaces can be formed within the first-tier stepped cavities 169 of the contact region 200 by patterning the first vertically alternating sequence (132, 142). For example, a combination of a sacrificial hard mask layer and a trimming mask layer may be employed to form the first stepped surfaces. Each first-tier stepped cavity 169 comprises a respective contiguous set of stepped surfaces of the first vertically alternating sequence (132, 142). The lateral extents of the first-tier sacrificial material layers 142 vary with a vertical distance from the substrate 9 in each first-tier stepped cavity 169. Each of the first-tier sacrificial material layers 142 has a respective physically exposed horizontal top surface segment within each first-tier stepped cavity 169. The sidewalls of each first-tier staircase region may be tapered. The area in which the physically exposed horizontal surface segments of the first-tier stepped surfaces of a first-tier stepped cavity 169 is located within a plan view is herein referred to as a first-tier stepped surface area.

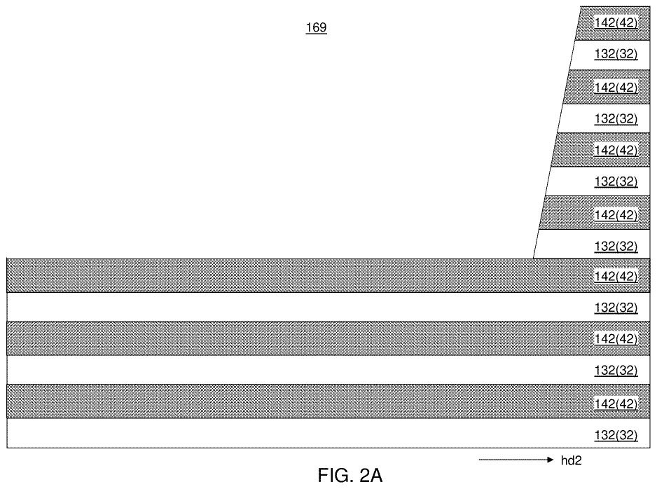

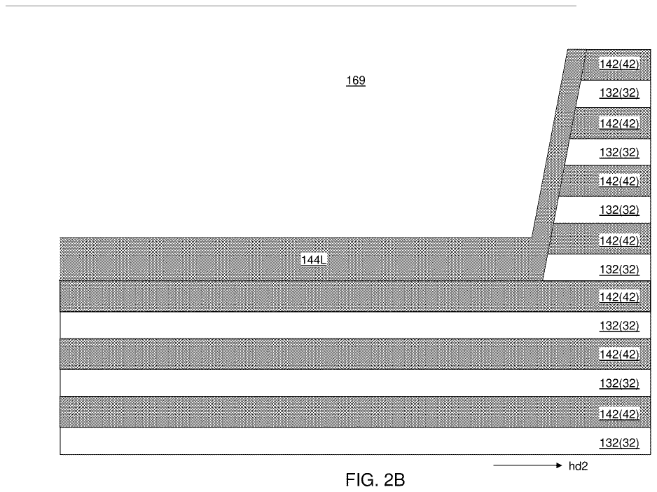

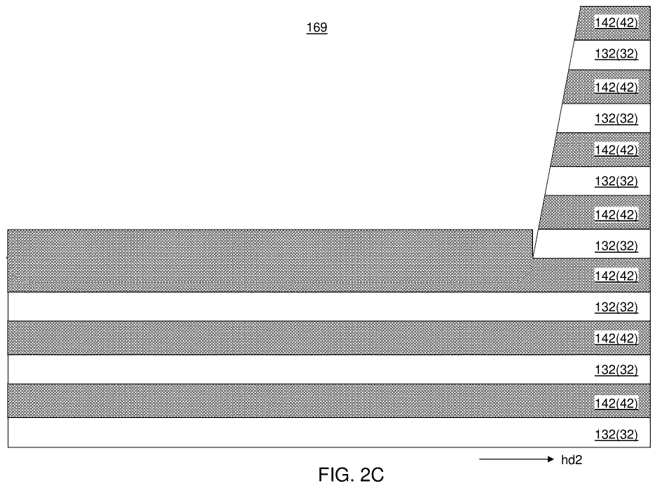

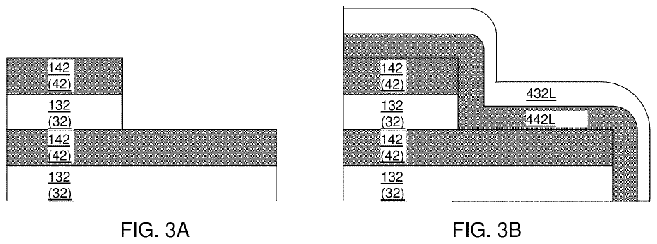

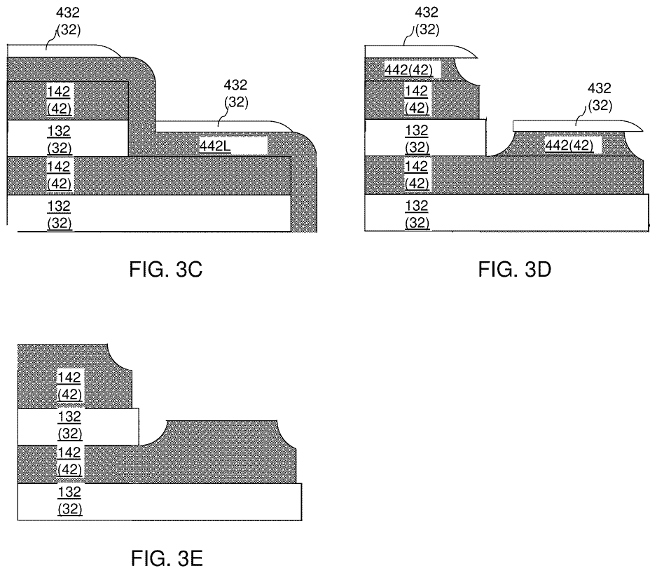

Physically exposed horizontally-extending portions of the first-tier sacrificial material layers 142 may be locally thickened by performing suitable processing steps. Various processing schemes may be performed to locally thicken the physically exposed horizontally-extending portions of the of the first-tier sacrificial material layers 142. FIG. 2A-2C and FIG. 3A-3E illustrates two exemplary sequence of processing steps that may be employed to locally thicken the first-tier sacrificial material layers 142.

FIG. 2A-2C are sequential vertical cross-sectional views of a region of the first exemplary structure during thickening of physically-exposed portions of the first-tier sacrificial material layers according to an embodiment of the present disclosure.

Referring to FIG. 2A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50 % to 300 % of the thickness of each first-tier sacrificial material layer 142.

Referring to FIG. 2B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range from 125 % to 250 %, such as from 150 % to 200 %, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 2C, portions of the non-conformal sacrificial material layer 144L that are deposited outside the areas of the first-tier stepped cavities 169 can be removed, for example, by covering the areas of the first-tier stepped cavities 169 with patterned photoresist materials without covering sidewalls of the first-tier stepped cavities 169, and by performing an etch process that etches unmasked portions of the material of the non-conformal sacrificial material layer 144L. Physically exposed portions of the first-tier sacrificial material layers 142 may be locally thickened within the first-tier stepped cavities 169.

Local thickening of the physically exposed portions of the first-tier sacrificial material layers 142 may be performed employing alternative methods. FIG. 3A-3E are sequential vertical cross-sectional views of a region of the first exemplary structure during a sequence of processing steps that may be employed to locally thicken the physically-exposed portions of the first-tier sacrificial material layers according to an embodiment of the present disclosure.

Referring to FIG. 3A, a region of the first-tier stepped surfaces in a first-tier stepped cavity 169 after the processing steps of FIG. 1A-1C is illustrated.

Referring to FIG. 3B, an additive sacrificial material layer 442L can be conformally deposited by a conformal deposition process such as a low pressure chemical vapor deposition process. The thickness of the additive sacrificial material layer 442L may be in a range from 40 % to 300 %, such as from 60 % to 150 %, of the thickness of each first-tier sacrificial material layer 142. The additive sacrificial material layer 442L may comprise the same material as the first-tier sacrificial material layers 142. For example, if the first-tier sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 3C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that are remaining portions of the non-conformal cover material layer 432L that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 3D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first-tier sacrificial material layers 142.

Referring to FIG. 3E, a selective etch process may be optionally performed to remove the cover material plates 432 without removing the materials of the sacrificial material plates 442 or the first-tier sacrificial material layers 142. The material of sacrificial material plates 442 may be the same as the material of the first-tier sacrificial material layers 142. Thus, the first-tier sacrificial material layers 142 incorporate the sacrificial material plates 442, and are locally thickened in the regions of the first stepped surfaces.

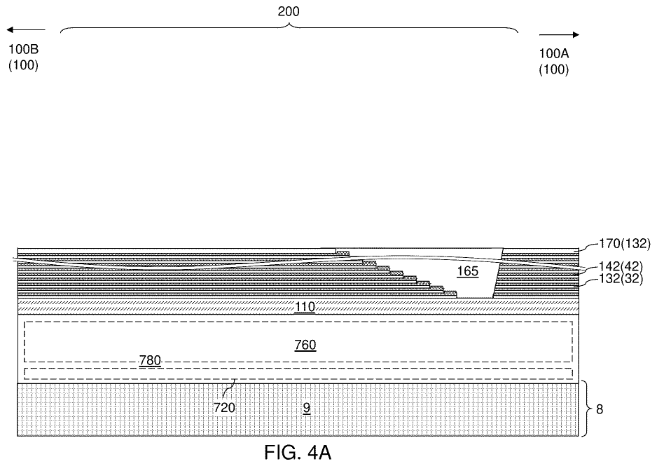

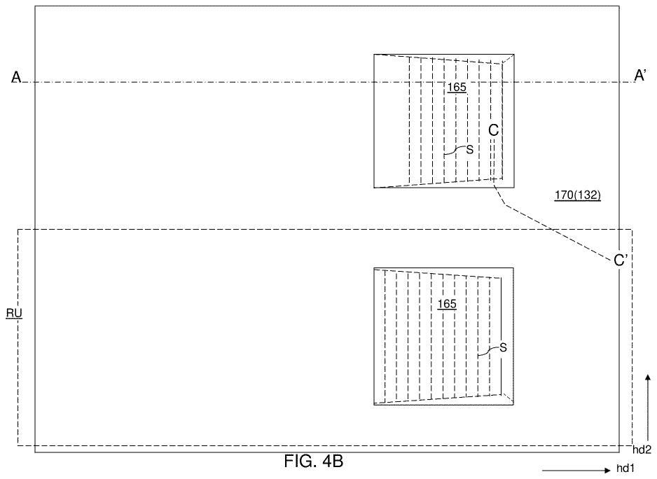

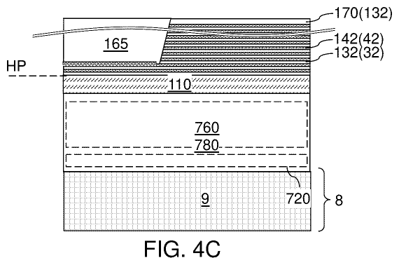

Referring to FIG. 4A-4C, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in the contact region 200 w between the first memory array region 100A and the second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

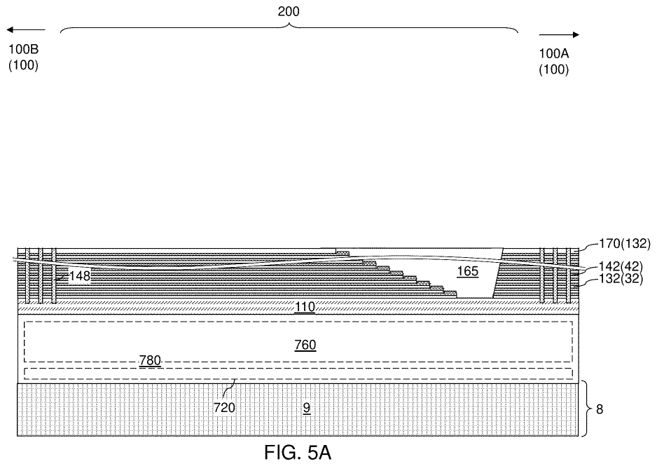

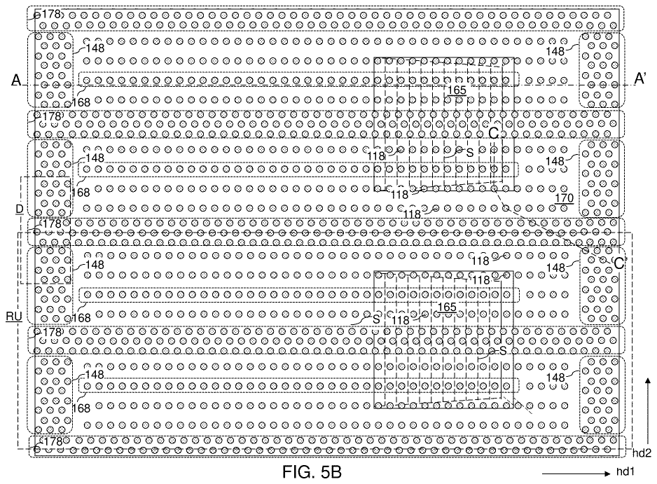

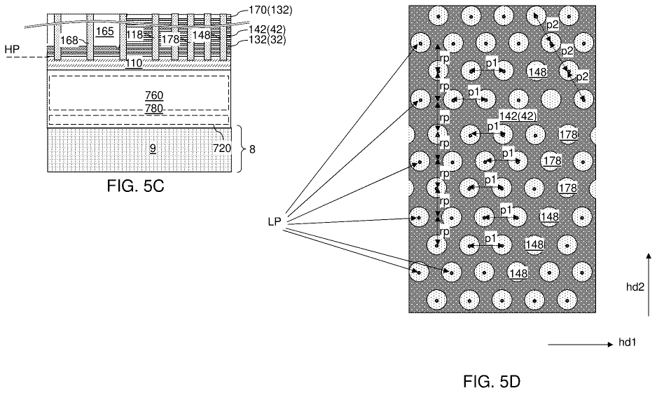

Referring to FIG. 5A-5D, various first-tier openings may be formed through the first vertically alternating sequence (132, 142) and into the semiconductor material layer 110. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the semiconductor material layer 110 by a first anisotropic etch process to form the various first-tier openings concurrently. The various first-tier openings may include first-tier memory openings (which are subsequently filled with sacrificial first-tier memory opening fill structures 148) formed in the memory array regions (100A, 100B), first-tier support openings (which are subsequently filled with sacrificial first-tier support opening fill structures 118) formed in the contact region 200, first-tier contact openings (which are subsequently filled with sacrificial first-tier contact opening fill structures 168) formed in the contact region 200, and first-tier isolation openings (which are subsequently filled with sacrificial first-tier isolation structures 178) that are formed in elongated rectangular areas that extend through the contact region 200 and the memory array regions (100A, 100B) along the first horizontal direction hd1 and laterally spaced apart from each other with a periodicity.

In one embodiment, each of the first-tier memory openings, the first-tier support openings, the first-tier isolation openings, and the first-tier contact openings may have a respective circular horizontal cross-sectional shape. In one embodiment, the first-tier memory openings and the first-tier isolation openings may have the same circular horizontal cross-sectional shape.

In one embodiment, there may be a cluster of at least three adjacent rows of first-tier isolation openings extending along the first horizontal direction hd1 between rows of first-tier support openings and the first-tier contact openings in the contact region 200, as viewed along the second horizontal direction hd2. In one embodiment, the width of the repetition unit RU along the second horizontal direction hd2 may be an integer multiple of the periodicity of the regions of the first-tier isolation openings. In the illustrated example of FIG. 5B, the width of the repetition unit RU along the second horizontal direction hd2 is twice the periodicity of the regions of the first-tier isolation openings along the second horizontal direction hd2. In one embodiment, the rectangular regions of the first-tier isolation openings may comprise first-type regions having an areal overlap with a respective one of the first-tier retro-stepped dielectric material portions 165, and second-type regions that are located between a respective neighboring pair of first-tier retro-stepped dielectric material portions 165.

Each cluster of first-tier memory openings may be formed as a two-dimensional periodic array of first-tier memory openings. The first-tier support openings are openings that are formed in the contact region 200, and are subsequently employed to form support pillar structures. Each first-tier contact opening is formed in a respective area in which a respective through-via contact structure is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

In one embodiment, the diameters of the first-tier memory openings is within 40% of the diameters of the first-tier isolation openings. For example, the diameters of the first-tier memory openings differ by 0 to 25% from the diameters of the first-tier isolation openings. In one embodiment, the pitch of the first-tier memory openings along the second horizontal direction is within 50% of the pitch of the first-tier isolation openings along the second horizontal direction hd2. For example, the pitch of the first-tier memory openings differs by 0 to 30% from the pitch of the first-tier isolation openings along the second horizontal direction hd2.

In one embodiment, the geometrical centers of the first-tier memory openings and the first-tier isolation openings may be formed at lattice points LP of a two-dimensional periodic array. As used herein, a two-dimensional periodic array refers to a structured arrangement of elements that repeat periodically in a plane along two independent directions. This periodicity is defined by two non-parallel translation vectors, a₁ and a₂, which establish the fundamental repeating unit, or unit cell, of the array. The elements of the array are positioned at intervals defined by integer multiples of the translation vectors, such that a translation of the array by any integer multiple of a₁ or a₂ aligns the array with its original configuration. The two-dimensional periodic array may include various lattice configurations, such as square, rectangular, centered rectangular, hexagonal, or oblique, depending on the geometric and symmetry properties of the arrangement.

In one embodiment shown in FIG. 5D, the geometrical centers of the first-tier memory openings and the first-tier isolation openings may be formed at lattice points LP of a two-dimensional hexagonal periodic array in a plan view. In this case, the lateral distance between geometrical centers of each neighboring pair of first-tier memory openings that are spaced apart along the first horizontal direction hd1 may be a first pitch p1. The lateral distance between geometrical centers of each neighboring pair of first-tier isolation openings that are spaced apart along the first horizontal direction hd1 may also be the first pitch p1. The lateral distance between geometrical centers of each neighboring pair of first-tier openings selected from the first-tier isolation openings and the first-tier memory openings and are spaced apart along a repetition direction of the two-dimensional hexagonal periodic array may be a second pitch p2. In one embodiment, the geometrical centers of the first-tier memory openings and the first-tier isolation openings may be formed at lattice points LP of a two-dimensional regular hexagonal periodic array. In this case, the second pitch p2 may be the same as the first pitch p1, and the repetition direction that is not parallel to the first horizontal direction hd1 may be azimuthally rotated relative to the first horizontal direction hd1 by 60 degrees.

The first-tier isolation openings may be arranged in rows that laterally extend along the first horizontal direction hd1. The first-tier memory openings may be arranged in rows that laterally extend along the first horizontal direction hd1. The rows of the first-tier memory openings and the rows of the first-tier isolation openings may be arranged such that each geometrical center of the first-tier memory openings and the first-tier isolation openings is located at lattice points LP of a two-dimensional periodic array, such as a regular hexagonal array. The center-to-center distance between each neighboring pairs of rows within the collection of the rows of first-tier memory openings and the rows of first-tier isolation openings may be the same, and is herein referred to as a row periodicity rp.

Thus, in one embodiment, geometrical centers of the first-tier memory openings and first-tier isolation openings are formed at lattice points LP of a two-dimensional periodic array in any plan view, which may be, for example, a horizontal cross-sectional view or a top-down view. The direction of periodicity of the two-dimensional periodic array comprises the first horizontal direction hd1. In one embodiment, the two-dimensional periodic array comprises a hexagonal array having a first periodicity direction along the first horizontal direction hd1.

In one embodiment, the cluster of three rows of first-tier isolation openings may be provided between each neighboring clusters of first-tier memory openings in the memory array regions (100A, 100B). In one embodiment, three or more clusters of first-tier memory openings in a memory array region (100A or 100B) may be laterally spaced apart from each other by two or more rectangular areas of first-tier isolation openings. Each rectangular area of first-tier isolation openings may comprise at least three rows, such as exactly three rows, of first-tier isolation openings. All geometrical centers of the first-tier memory openings located within the three or more clusters and all intervening rows of first-tier isolation openings may be located at a subset of the lattice points LP of the two-dimensional periodic array.

Sacrificial first-tier opening fill structures (148, 168, 118, 178) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., amorphous silicon or polysilicon), silicon-germanium, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

Portions of the deposited sacrificial first-tier fill material may be removed from above the topmost layer of the first vertically alternating sequence (132, 142) (e.g., from above the first-tier insulating cap layer 170). For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 168, 118, 178). Specifically, each remaining portion of the sacrificial first-tier fill material in a first-tier memory opening constitutes a sacrificial first-tier memory opening fill structure 148. Each remaining portion of the sacrificial first-tier fill material in a first-tier isolation opening constitutes a sacrificial first-tier isolation opening fill structure 168. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 178. The various sacrificial first-tier opening fill structures (148, 168, 118, 178) are concurrently formed, i.e., employing a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 168, 118, 178) may be coplanar with the top surface of the first-tier insulating cap layer 170. Each of the sacrificial first-tier opening fill structures (148, 168, 118, 178) may optionally include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. A subset of the first-tier contact openings can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

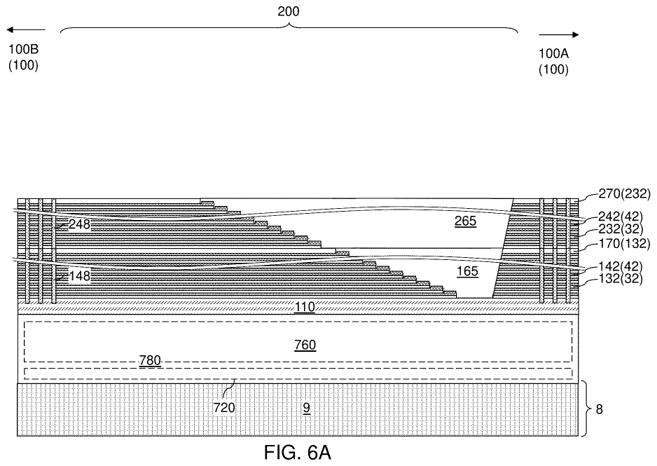

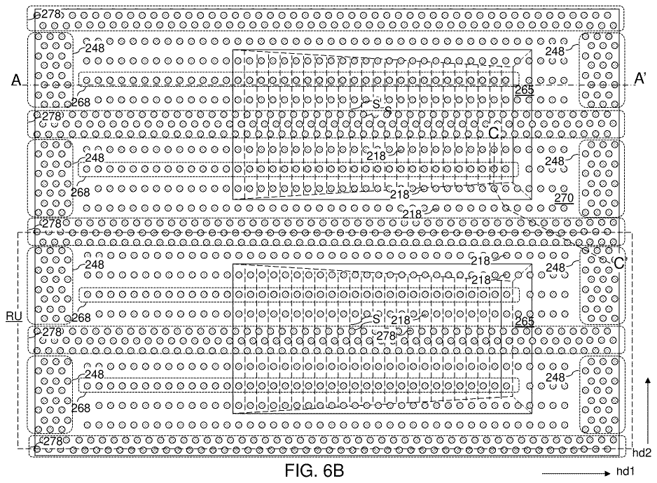

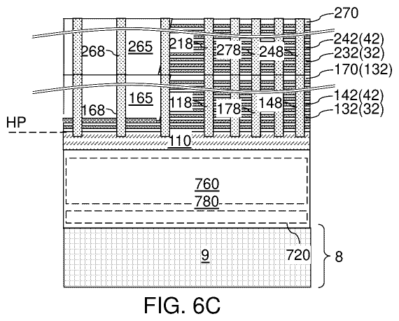

Referring to FIG. 6A-6C, a second vertically alternating sequence of second-tier insulating layers 232 and second-tier sacrificial material layers 242 can be formed. Each of the second-tier insulating layers 232 is an insulating layer 32 that continuously extends over the entire area of the semiconductor material layer 110 and may have a uniform thickness throughout. Each of the second-tier sacrificial material layers 242 is a sacrificial material layer 42 that includes a dielectric material and continuously extends over the entire area of the semiconductor material layer 110 and may have a uniform thickness throughout. The second-tier insulating layers 232 can have the same material composition and thickness as the first-tier insulating layers 132. The second-tier sacrificial material layers 242 can have the same material composition and thickness as the first-tier sacrificial material layers 142. The topmost second-tier insulating layer 232 is herein referred to as a second-tier insulating cap layer 270. The second-tier insulating cap layer 270 may have a greater thickness than each of the underlying second-tier insulating layers 232.

Second stepped surfaces can be formed within each second-tier stepped cavity in the contact region 200, which will be filled with respective second-tier retro-stepped dielectric material portions 265. For example, a combination of a sacrificial hard mask layer and a trimming mask layer may be employed to form the second stepped surfaces. Generally, the processing steps described with reference to FIG. 2A-2E can be performed with a change in the masking pattern to form second-tier stepped cavities. Each set of second stepped surfaces may be laterally offset along the first horizontal direction hd1 relative to an adjacent and underlying set of first stepped surfaces of the first vertically alternating sequence (132, 142).

Each second-tier stepped cavity comprises a respective contiguous set of stepped surfaces of the second vertically alternating sequence (232, 242). Each of the second-tier sacrificial material layers 242 has a respective physically exposed horizontal top surface segment within each second-tier stepped cavity.

The sidewalls of each second-tier staircase region may be tapered. The area in which the physically exposed horizontal surface segments of the second-tier stepped surfaces of a second-tier stepped cavity is located within a plan view is herein referred to as a second-tier stepped surface area.

In one embodiment, each first-tier stepped surface area may have a rectangular shape in the plan view. Physically exposed portions of the second-tier sacrificial material layers 242 may be locally thickened by performing a sequence of processing steps described with reference to FIG. 3A-3C or by performing a sequence of processing steps described with reference to FIG. 4A-4E.

A second dielectric fill material (such as undoped silicate glass (i.e., silicon oxide) or doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second-tier stepped cavity constitutes a second-tier retro-stepped dielectric material portion 265. Generally, the second-tier retro-stepped dielectric material portions 265 can be formed in the contact region 200, located between the first memory array region 100A and the second memory array region 100B. The planar top surface of each second-tier retro-stepped dielectric material portion 265 can be located within a horizontal plane including the top surface of the second-tier insulating cap layer 270.

Each repetition unit RU comprises a respective set of second-tier retro-stepped dielectric material portions 265. Each repetition unit RU may comprise a plurality of second-tier retro-stepped dielectric material portions 265. Each second-tier retro-stepped dielectric material portion 265 has a plurality of sidewalls that are perpendicular to the second horizontal direction.

The processing steps described with reference to FIG. 5A-5E may be performed with necessary changes to form various second-tier openings through the second vertically alternating sequence (232, 242). A photoresist layer (not shown) may be applied over the second vertically alternating sequence (232, 242) and may be lithographically patterned to form various openings therethrough. The pattern of openings in the photoresist layer may be transferred through the second vertically alternating sequence (232, 242) by a second anisotropic etch process to form the various second-tier openings concurrently.

Sacrificial second-tier opening fill structures (248, 268, 218, 278) may be formed in the various second-tier openings. A sacrificial second-tier fill material is concurrently deposited in each of the second-tier openings. The sacrificial second-tier fill material and an optional thin etch stop liner may be the same as described above. The sacrificial second-tier fill material may be formed by a non-conformal deposition or a conformal deposition method. Portions of the deposited sacrificial second-tier fill material may be removed from above the topmost layer of the second vertically alternating sequence (232, 242), such as from above the second-tier insulating cap layer 270.

Remaining portions of the sacrificial second-tier fill material comprise sacrificial second-tier opening fill structures (248, 268, 218, 278). Specifically, each remaining portion of the sacrificial second-tier fill material in a second-tier memory opening constitutes a sacrificial second-tier memory opening fill structure 248. Each remaining portion of the sacrificial second-tier fill material in a second-tier contact opening constitutes a sacrificial second-tier contact opening fill structure 268. Each remaining portion of the sacrificial second-tier fill material in a second-tier support opening constitutes a sacrificial second-tier support opening fill structure 218. Each remaining portion of the sacrificial second-tier fill material in a second-tier isolation opening constitutes a sacrificial second-tier isolation opening fill structure 278. The various sacrificial second-tier opening fill structures (248, 268, 218, 278) are concurrently formed, i.e., during the same set of processes including the deposition and planarization processes.

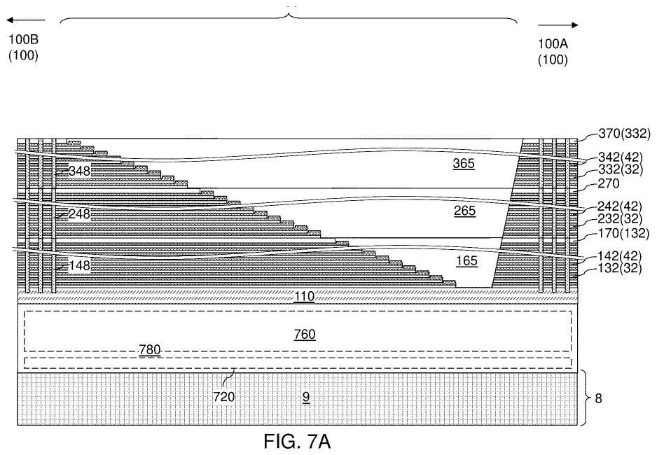

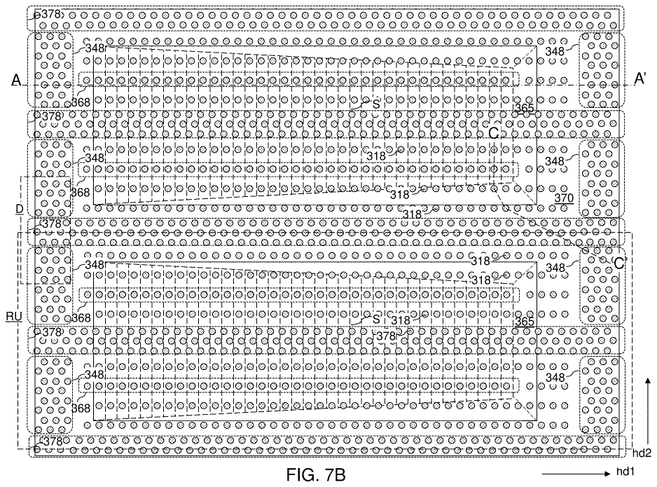

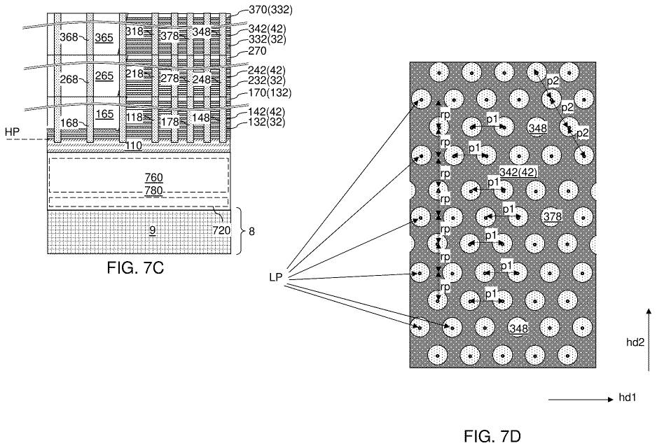

Referring to FIG. 7A-7D, a third vertically alternating sequence of third-tier insulating layers 332 and third-tier sacrificial material layers 342 can be formed. Each of the third-tier insulating layers 332 is an insulating layer 32 that continuously extends over the entire area of the semiconductor material layer 110 and may have a uniform thickness throughout. Each of the third-tier sacrificial material layers 342 is a sacrificial material layer 42 that includes a dielectric material and continuously extends over the entire area of the semiconductor material layer 110 and may have a uniform thickness throughout. The third-tier insulating layers 332 can have the same material composition and thickness as the first-tier insulating layers 132. The third-tier sacrificial material layers 342 can have the same material composition and thickness as the first-tier sacrificial material layers 142. The topmost third-tier insulating layer 332 is herein referred to as a third-tier insulating cap layer 370. The third-tier insulating cap layer 370 may have a greater thickness than each of the underlying third-tier insulating layers 332.

Third stepped surfaces can be formed within each third-tier stepped cavity in the contact region 200, which will be filled with respective third-tier retro-stepped dielectric material portions 365. For example, a combination of a sacrificial hard mask layer and a trimming mask layer may be employed to form the third stepped surfaces. Generally, the processing steps described with reference to FIG. 3A-3E can be performed with a change in the masking pattern to form third-tier stepped cavities. Each set of third stepped surfaces may be laterally offset along the first horizontal direction hd1 relative to an adjacent and underlying set of second stepped surfaces of the second vertically alternating sequence (232, 242).

Each third-tier stepped cavity comprises a respective contiguous set of stepped surfaces of the third vertically alternating sequence (332, 342). Each of the third-tier sacrificial material layers 342 has a respective physically exposed horizontal top surface segment within each third-tier stepped cavity. The sidewalls of each third-tier staircase region may be tapered. The area in which the physically exposed horizontal surface segments of the third-tier stepped surfaces of a third-tier stepped cavity is located within a plan view is herein referred to as a third-tier stepped surface area. In one embodiment, each first-tier stepped surface area may have a rectangular shape in the plan view. Physically exposed portions of the third-tier sacrificial material layers 342 may be locally thickened by performing a sequence of processing steps described with reference to FIG. 2A-2C or by performing a sequence of processing steps described with reference to FIG. 3A-3E.

A third dielectric fill material (such as undoped silicate glass or doped silicate glass) can be deposited in each third-tier stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third-tier stepped cavity constitutes a third-tier retro-stepped dielectric material portion 365. Generally, the third-tier retro-stepped dielectric material portions 365 can be formed in the contact region 200, located between the first memory array region 100A and the second memory array region 100B. The planar top surface of each third-tier retro-stepped dielectric material portion 365 can be located within a horizontal plane including the top surface of the third-tier insulating cap layer 370.

Each repetition unit RU comprises a respective set of third-tier retro-stepped dielectric material portions 365. Each repetition unit RU may comprise a plurality of third-tier retro-stepped dielectric material portions 365, Each third-tier retro-stepped dielectric material portion 365 has a plurality of sidewalls that are perpendicular to the third horizontal direction. The processing steps described with reference to FIG. 5A-5E may be performed with necessary changes to form various third-tier openings through the third vertically alternating sequence (332, 342). A photoresist layer (not shown) may be applied over the third vertically alternating sequence (332, 342) and may be lithographically patterned to form various openings therethrough. The pattern of openings in the photoresist layer may be transferred through the third vertically alternating sequence (332, 342) by a third anisotropic etch process to form the various third-tier openings concurrently.

Sacrificial third-tier opening fill structures (348, 368, 318, 378) may be formed in the various third-tier openings. For example, a sacrificial third-tier fill material is concurrently deposited in each of the third-tier openings. The sacrificial third-tier fill material and an optional thin etch stop liner may be the same as described above. The sacrificial third-tier fill material may be formed by a non-conformal deposition or a conformal deposition method. Portions of the deposited sacrificial third-tier fill material may be removed from above the topmost layer of the third vertically alternating sequence (332, 342), such as from above the third-tier insulating cap layer 370.

Remaining portions of the sacrificial third-tier fill material comprise sacrificial third-tier opening fill structures (348, 368, 318, 378). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. Each remaining portion of the sacrificial third-tier fill material in a third-tier isolation opening constitutes a sacrificial third-tier isolation opening fill structure 378. The various sacrificial third-tier opening fill structures (348, 368, 318, 378) are concurrently formed, i.e., during the same set of processes, including the deposition and planarization processes. The top surfaces of the sacrificial third-tier opening fill structures (348, 368, 318, 378) may be coplanar with the top surface of the third-tier insulating cap layer 370. Each of the sacrificial third-tier opening fill structures (348, 368, 318, 378) may optionally include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure. The combination of the first vertically alternating sequence (132, 232), the second vertically alternating sequence (232, 242), and the third vertically alternating sequence (332 342) may comprise a combined vertically alternating sequence (32, 42) of continuous insulating layers 32 and continuous sacrificial material layers 42.

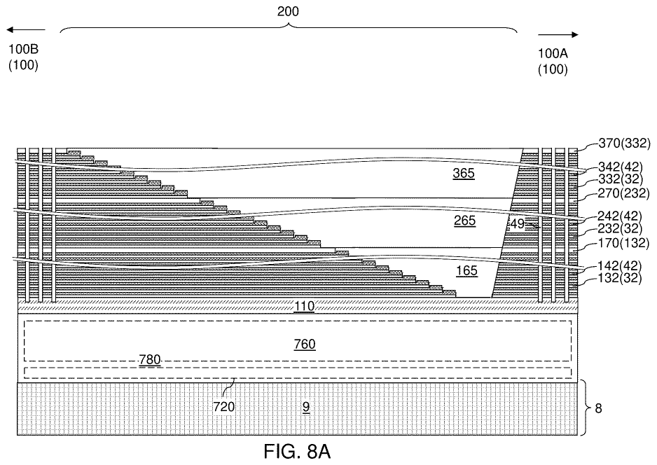

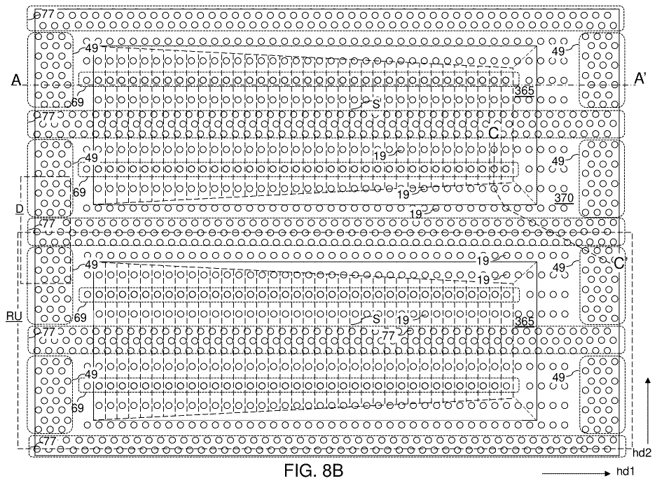

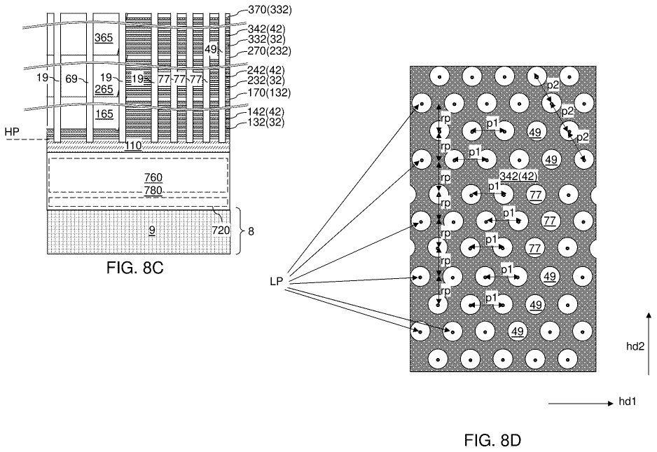

Referring to FIG. 8A-8C, the sacrificial fill materials of the sacrificial third-tier opening fill structures (348, 368, 318, 378), the sacrificial second-tier opening fill structures (248, 268, 218, 278), and the sacrificial first-tier opening fill structures (148, 168, 118, 178) can be removed selectively to the materials of the insulating layers 32, the sacrificial material layers 42, and the semiconductor material layer 110. memory openings 49 are formed in the voids from which the sacrificial fill materials of the sacrificial memory opening fill structures (148, 248, 348) are removed. Contact openings 69 are formed in the voids from which the sacrificial fill materials of the sacrificial contact opening fill structures (168, 268, 368) are removed. Support openings 19 are formed in the voids from which the sacrificial fill materials of the sacrificial support opening fill structures (118, 218, 318) are removed. isolation openings 77 are formed in the voids from which the sacrificial fill materials of the sacrificial support opening fill structures (178, 278, 378) are removed.

In one embodiment, each of the memory openings 49, the support openings 19, the isolation openings 77, and the contact openings 69 may have a respective circular horizontal cross-sectional shape. In one embodiment, the memory openings 49 and the isolation openings 77 may have the same circular horizontal cross-sectional shape, and a diameter which differs by 40% or less, such as 0 to 25%. In one embodiment, the pitch along the second horizontal direction hd2 (i.e., the row periodicity, rp) between the rows of the memory openings 49 and the isolation openings 77 differs by 50% or less, such as 0 to 30%. In one embodiment, the row pitch differs by zero percent (i.e., the row periodicity, rp, is the same).

In one embodiment shown in FIG. 8D, the geometrical centers of the memory openings 49 and the isolation openings 77 may be formed at lattice points LP of a two-dimensional hexagonal periodic array in a plan view. In this case, the lateral distance between geometrical centers of each neighboring pair of memory openings 49 that are spaced apart along the first horizontal direction hd1 may be a first pitch p1. The lateral distance between geometrical centers of each neighboring pair of isolation openings 77 that are spaced apart along the first horizontal direction hd1 may be the first pitch p1. The lateral distance between geometrical centers of each neighboring pair of openings selected from the isolation openings 77 and the memory openings 49 along a repetition direction of the two-dimensional hexagonal periodic array may be a second pitch p2. In one embodiment, the geometrical centers of the memory openings 49 and the isolation openings 77 may be formed at lattice points LP of a two-dimensional regular hexagonal periodic array. In this case, the second pitch p2 may be the same as the first pitch p1, and the repetition direction that is not parallel to the first horizontal direction hd1 may be azimuthally rotated relative to the first horizontal direction hd1 by 60 degrees.

The isolation openings 77 may be arranged in rows that laterally extend along the first horizontal direction hd1. The memory openings 49 may be arranged in rows that laterally extend along the first horizontal direction hd1. The rows of the memory openings 49 and the rows of the isolation openings 77 may be arranged such that each geometrical center of the memory openings 49 and the isolation openings 77 is located at lattice points LP of a two-dimensional periodic array, such as a regular hexagonal array. The center-to-center distance between each neighboring pairs of rows within the collection of the rows of memory openings 49 and the rows of isolation openings 77 may be the same, and is herein referred to as a row periodicity rp.

Generally, geometrical centers of the memory openings 49 and isolation openings 77 are formed at lattice points LP of a two-dimensional periodic array in any plan view, which may be, for example, a horizontal cross-sectional view or a top-down view. The direction of periodicity of the two-dimensional periodic array comprises the first horizontal direction hd1. In one embodiment, the two-dimensional periodic array comprises a hexagonal array having a first periodicity direction along the first horizontal direction hd1.

In one embodiment shown in FIGS. 8B and 8D, three rows of isolation openings 77 may be provided between each neighboring clusters of memory openings 49. In one embodiment, three or more clusters of memory openings 49 in a memory array region (100A or 100B) may be laterally spaced apart from each other by two or more rectangular areas of isolation openings 77. Each rectangular area of isolation openings 77 may comprise at least three rows, such as exactly three rows of isolation openings 77. All geometrical centers of the memory openings 49 located within the three or more clusters and all intervening rows of isolation openings 77 may be located at a subset of the lattice points LP of the two-dimensional periodic array.

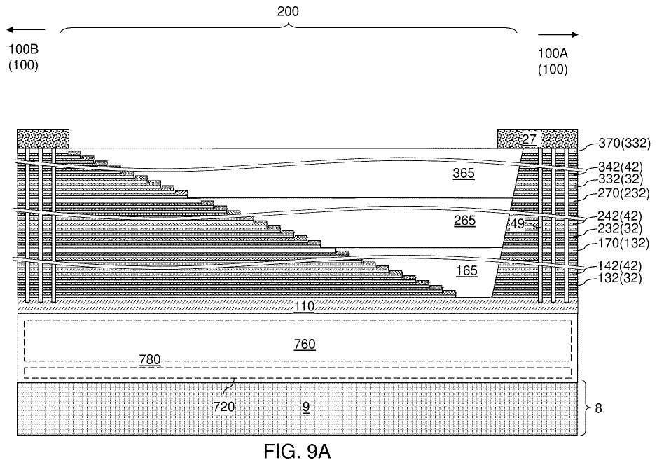

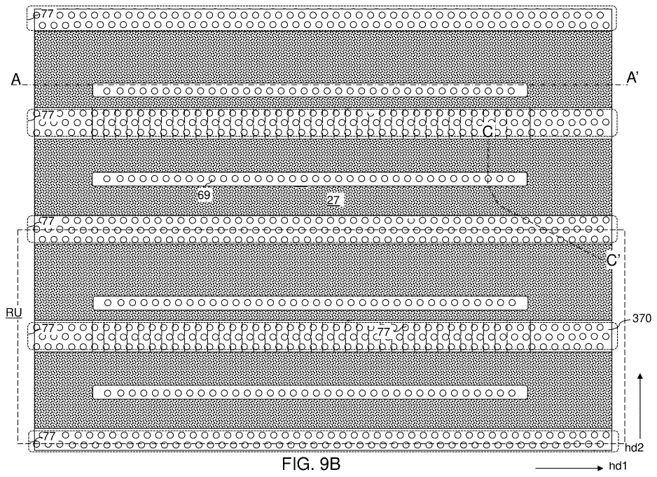

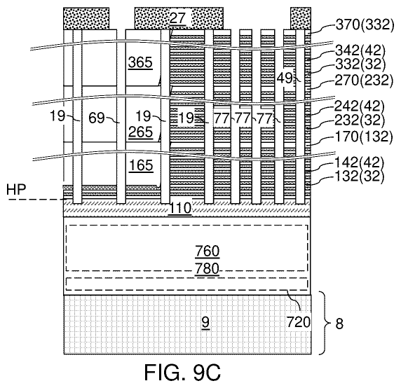

Referring to FIG. 9A-9C, a patterned mask layer 27 can be formed over the topmost tier structure (such as the third-tier structure). The patterned mask layer 27 comprises an etch mask material that may be anisotropically deposited. For example, the patterned mask layer 27 may comprise a patterning film comprising a carbon-based material, such as amorphous carbon or diamond-like carbon. The patterned mask layer 27 may be formed by anisotropically depositing a continuous material layer, by applying and lithographically patterning a photoresist layer over the continuous material layer, anisotropically etching unmasked portions of the continuous material layer, and removing the photoresist layer. The remaining portion of the continuous material layer constitutes the patterned mask layer 27.

According to an aspect of the present disclosure, the patterned mask layer 27 covers all memory openings 49 and all support openings 19 without covering any isolation opening 77 or any contact opening 69. In one embodiment, the patterned mask layer 27 may comprise elongated openings that laterally extend along the first horizontal direction hd1. A first subset of the elongated openings is formed over a respective rectangular area including a respective set of three rows of isolation openings 77. A second subset of the elongated openings may be formed over a respective rectangular area including a respective row of contact openings 69.

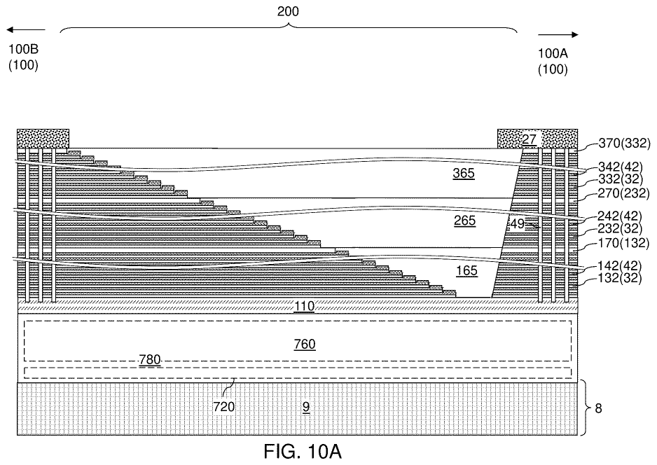

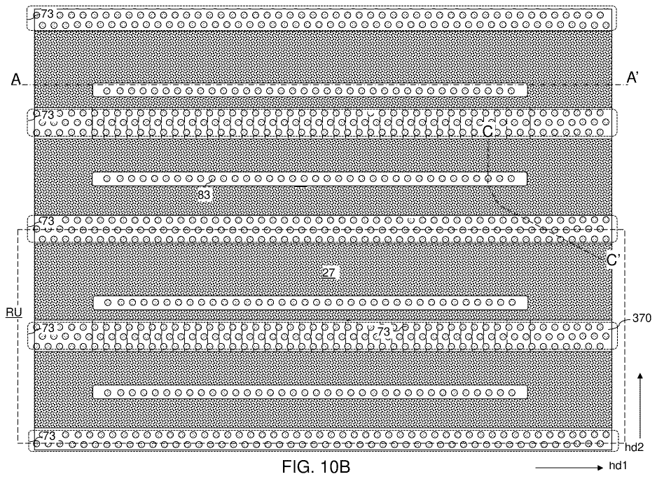

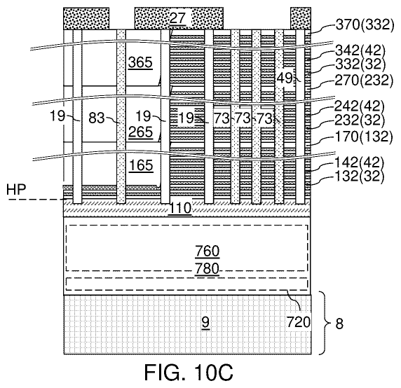

Referring to FIG. 10A-10C, a sacrificial fill material can be conformally deposited in the isolation openings 77 and the contact openings 69. The sacrificial fill material may comprise any material that may be employed for the sacrificial first-tier fill structures (148, 118, 138, 168), the sacrificial second-tier fill structures (248, 218, 238, 268), and the sacrificial third-tier fill structures (348, 318, 338, 368). A recess etch process can be performed to recess the sacrificial fill material from above the horizontal plane including the topmost surface of the topmost tier structure such as a the top surface of the third-tier insulating cap layer 370. Each remaining portion of the sacrificial fill material that fills an isolation opening 77 comprises a sacrificial isolation opening fill structure 73. Each remaining portion of the sacrificial fill material that fills a contact opening 69 comprises a sacrificial contact opening fill structure 83.

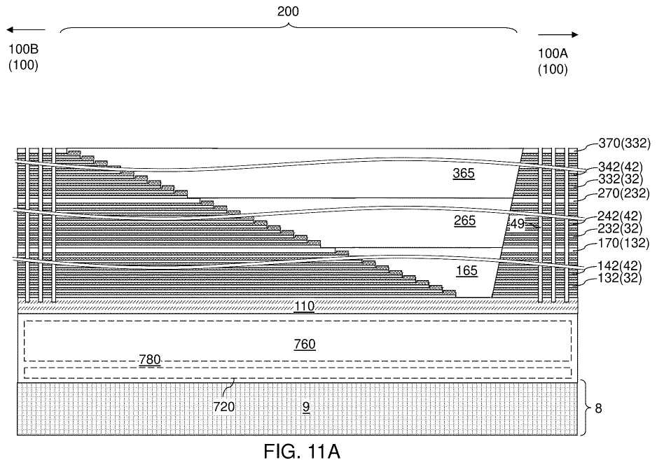

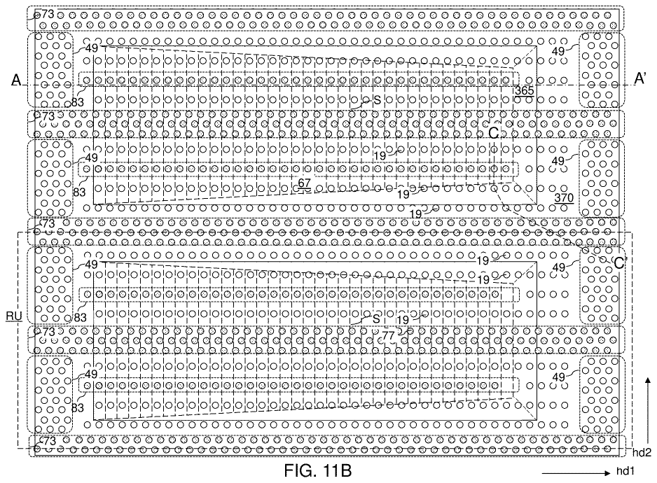

Referring to FIG. 11A-11C, the patterned mask layer 27 can be removed selective to the materials of the insulating layers 32, the sacrificial material layers 42, and the retro-stepped dielectric material portions (165, 265, 365). An ashing process or a selective etch process may be employed to remove the patterned mask layer 27. Cavities are formed in the memory openings 49 and in the support openings 19.

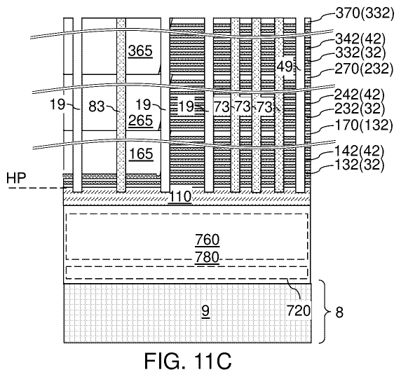

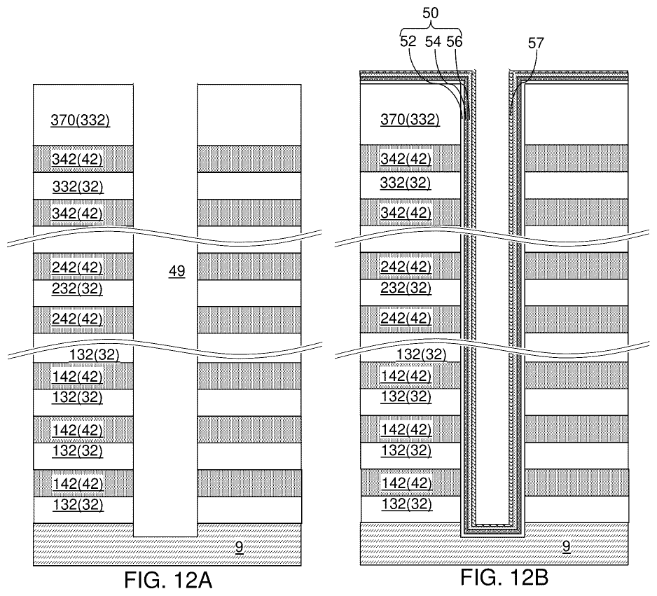

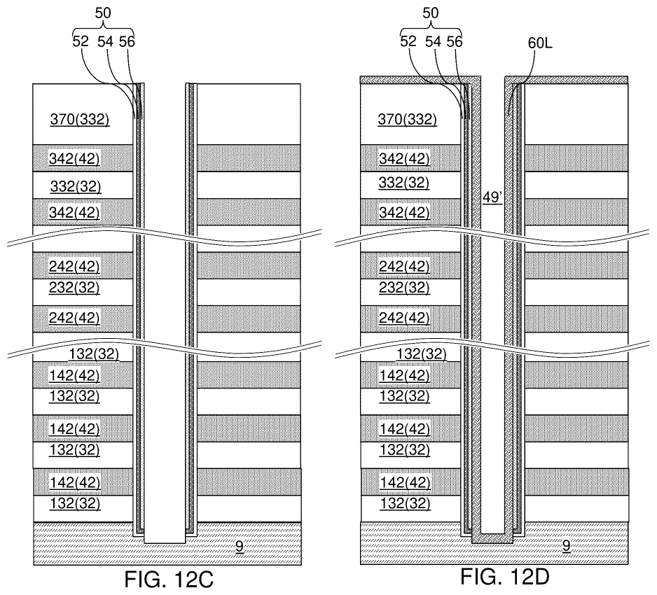

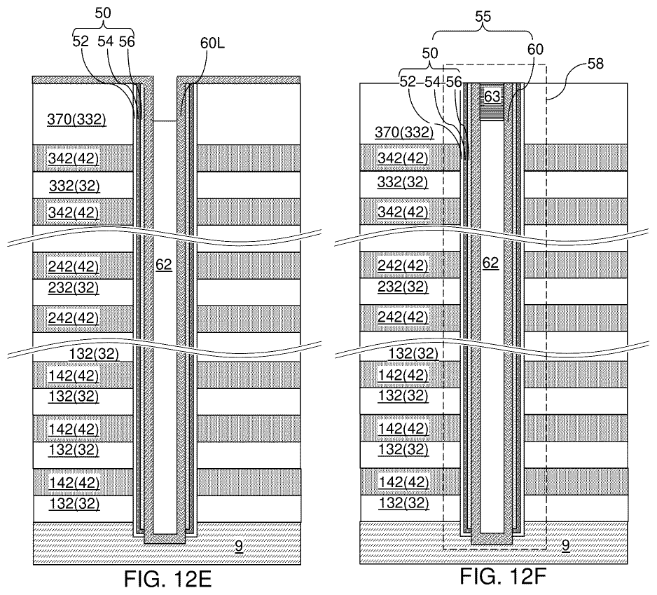

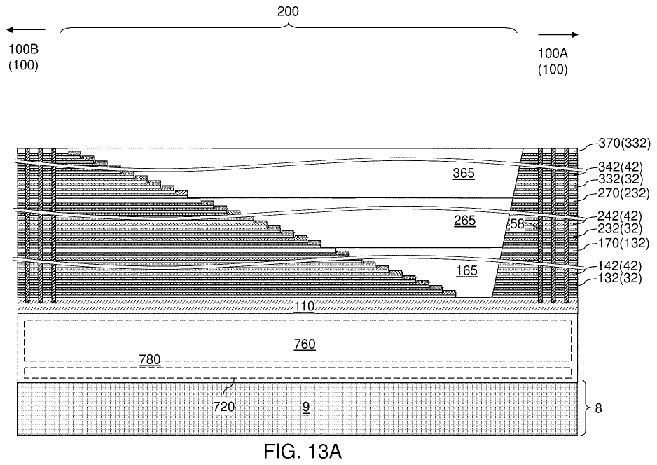

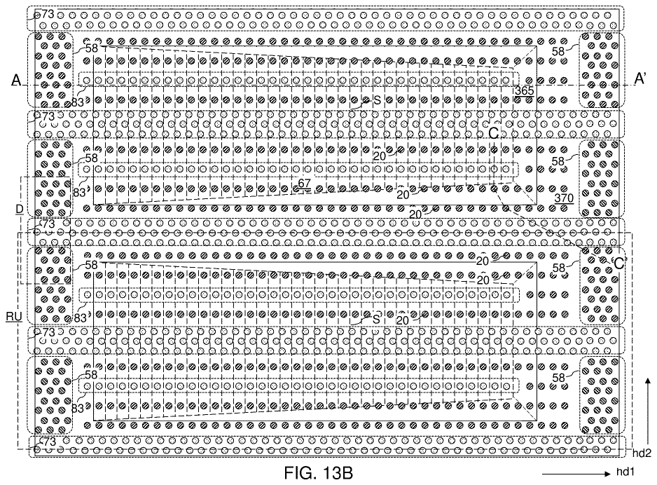

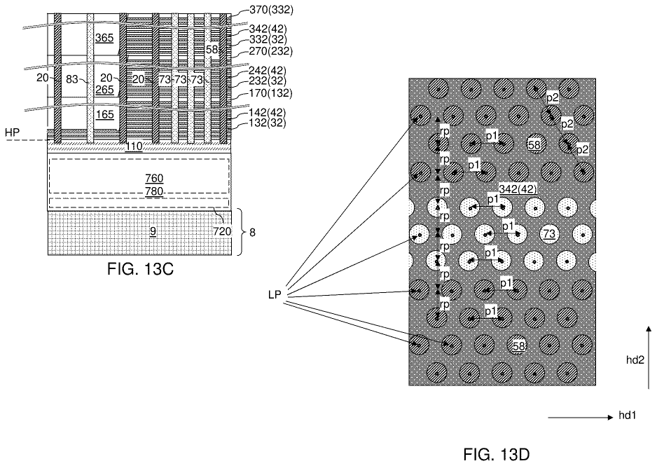

FIG. 12A-12F illustrate sequential vertical cross-sectional views of a memory opening 49 during formation of a memory opening fill structure 58 according to an embodiment of the present disclosure. The same structural changes occur in each support opening 19 to form support pillar structures 20 (shown in FIG. 13A-13C) in the support openings 19 during the processing steps illustrated in FIG. 12A-12F.

Referring to FIG. 12A, a memory opening 49 in the first exemplary structure of FIG. 11A-11C is illustrated in a vertical cross-sectional view.

Referring to FIG. 12B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 12C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 12D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphorus atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 12E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 12F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions (100A, 100B) of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

Referring to FIG. 13A-13D, the first exemplary structure is illustrated after the processing steps of FIG. 12F, i.e., after formation of the memory opening fill structures 58 in the memory openings 49. Support pillar structures 20 may be formed in the support openings 19 during the processing steps described with reference to FIG. 12A-13F. Each support pillar structure 20 may comprise the same set of structural elements as each memory opening fill structure 58.

Generally, each of the memory opening fill structures 58 comprises a respective vertical stack of memory elements (e.g., portions of the memory film 50) located at levels of the sacrificial material layers 42 within the memory openings 49, and further comprises a respective vertical semiconductor channel 60. In one embodiment, the geometrical centers of the memory opening fill structures 58 and the sacrificial isolation opening fill structures 73 may be formed at lattice points LP of a two-dimensional hexagonal periodic array in a plan view. In this case, the lateral distance between geometrical centers of each neighboring pair of memory opening fill structures 58 that are spaced apart along the first horizontal direction hd1 may be a first pitch p1. The lateral distance between geometrical centers of each neighboring pair of sacrificial isolation opening fill structures 73 that are spaced apart along the first horizontal direction hd1 may be the first pitch p1. The lateral distance between geometrical centers of each neighboring pair of openings selected from the sacrificial isolation opening fill structures 73 and the memory opening fill structures 58 that are spaced apart along a repetition direction of the two-dimensional hexagonal periodic array may be a second pitch p2. In one embodiment, the geometrical centers of the memory opening fill structures 58 and the sacrificial isolation opening fill structures 73 may be formed at lattice points LP of a two-dimensional regular hexagonal periodic array. In this case, the second pitch p2 may be the same as the first pitch p1, and the repetition direction that is not parallel to the first horizontal direction hd1 may be azimuthally rotated relative to the first horizontal direction hd1 by 60 degrees.

In one embodiment, each of the memory opening fill structures 58, the support pillar structures 20, the sacrificial isolation opening fill structures 73, and the sacrificial contact opening fill structures 83 may have a respective circular horizontal cross-sectional shape. In one embodiment, the memory opening fill structures 58 and the sacrificial isolation opening fill structures 73 may have the same circular horizontal cross-sectional shape.

The sacrificial isolation opening fill structures 73 may be arranged in rows that laterally extend along the first horizontal direction hd1. The memory opening fill structures 58 may be arranged in rows that laterally extend along the first horizontal direction hd1. The rows of the memory opening fill structures 58 and the rows of the sacrificial isolation opening fill structures 73 may be arranged such that each geometrical center of the memory opening fill structures 58 and the sacrificial isolation opening fill structures 73 is located at lattice points LP of a two-dimensional periodic array, such as a regular hexagonal array. The center-to-center distance between each neighboring pairs of rows within the collection of the rows of memory opening fill structures 58 and the rows of sacrificial isolation opening fill structures 73 may be the same, and is herein referred to as the row periodicity rp.

Generally, geometrical centers of the memory opening fill structures 58 and sacrificial isolation opening fill structures 73 are formed at lattice points LP of a two-dimensional periodic array in any plan view, which may be, for example, a horizontal cross-sectional view or a top-down view. The direction of periodicity of the two-dimensional periodic array comprises the first horizontal direction hd1. In one embodiment, the two-dimensional periodic array comprises a hexagonal array having a first periodicity direction along the first horizontal direction hd1.

In one embodiment, three rows of sacrificial isolation opening fill structures 73 may be provided between each neighboring clusters of memory opening fill structures 58. In one embodiment, three or more clusters of memory opening fill structures 58 in a memory array region (100A or 100B) may be laterally spaced apart among one another by two or more rectangular areas of sacrificial isolation opening fill structures 73. Each rectangular area of sacrificial isolation opening fill structures 73 may comprise at least three, such as exactly three rows of sacrificial isolation opening fill structures 73. All geometrical centers of the memory opening fill structures 58 located within the three or more clusters and all intervening rows of sacrificial isolation opening fill structures 73 may be located at a subset of the lattice points LP of the two-dimensional periodic array.

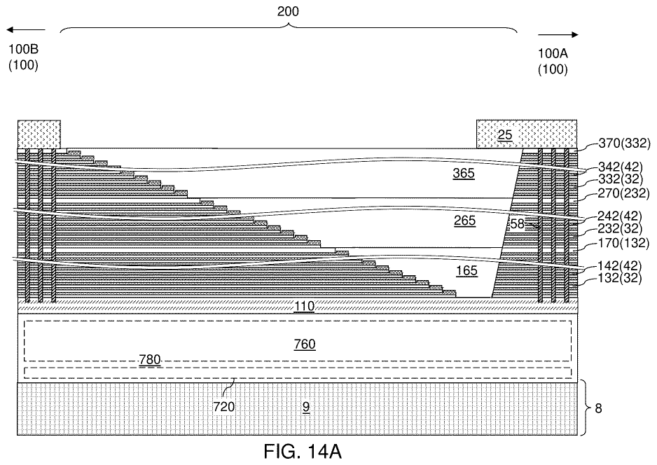

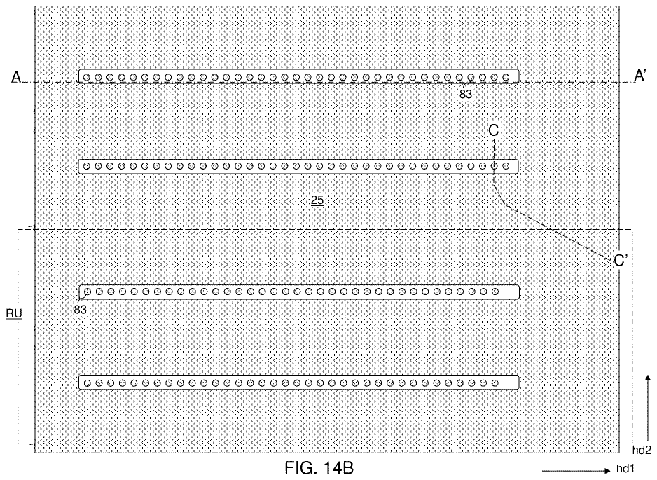

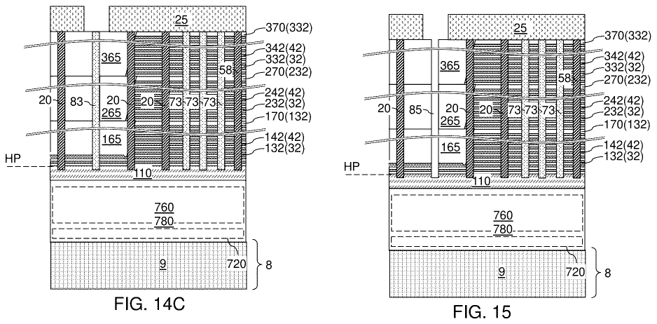

Referring to FIG. 14A-14C, a first photoresist layer 25 can be applied over the first exemplary structure, and can be lithographically patterned to form openings over the areas of the sacrificial contact opening fill structures 83. For example, the first photoresist layer 25 may comprise elongated openings laterally extending along the first horizontal direction hd1 and surrounding areas of a respective row of sacrificial contact opening fill structures 83.

Referring to FIG. 15, the sacrificial fill material of the sacrificial contact opening fill structures 83 can be removed selectively to the materials of retro-stepped dielectric material portions (165, 265, 365), the insulating layers 32, and the sacrificial material layers 42 by performing a selective etch process. Contact via cavities 85 are formed in the volumes from which the material of the sacrificial contact opening fill structures 83 is removed. Each contact via cavity 85 vertically extends from the horizontal plane including the planar top surfaces of the third-tier retro-stepped dielectric material portion 365 to the semiconductor material layer 110. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

In summary, an alternating stack (32, 42) of insulating layers 32 and sacrificial material layers 42 can be formed over a semiconductor material layer 110. Stepped surfaces can be formed by patterning the alternating stack (32, 42) in a staircase region. Physically exposed portions of the sacrificial material layers 42 are locally thickened after formation of the stepped surfaces. A retro-stepped dielectric material portion (165, 265, 365) is formed over the stepped surfaces. Contact via cavities 85 can be formed through a respective subset of the retro-stepped dielectric material portion (165, 265, 365) and a respective subset of the sacrificial material layers 42 within the alternating stack (32, 42). Each contact via cavity 85 may be formed through a locally thickened portion of a respective sacrificial material layer 42. Each contact via cavity 85 vertically extends through a thickened portions of only a single sacrificial material layer 42. In other words, each contact via cavity 85 vertically extends through no more than one thickened portion of the sacrificial material layers 42.

If the semiconductor material layer 110 comprises a semiconductor material, such as silicon, an oxidation process may be performed to convert physically exposed surface portions of the semiconductor material layer 110 underneath the contact via cavities 85 into semiconductor oxide (e.g., silicon oxide) spacer liners (not illustrated). The thickness of the semiconductor oxide spacer liners may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners.

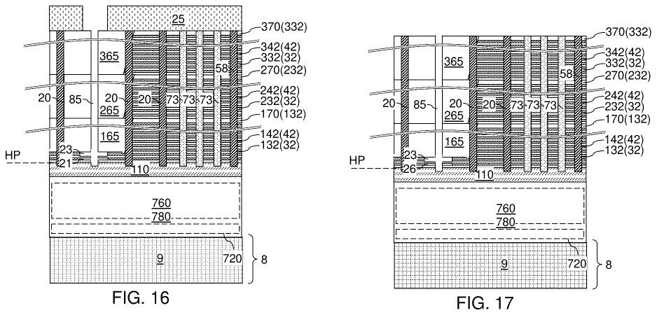

Referring to FIG. 16, a first isotropic etch process can be performed to isotropically etch proximal portions of the sacrificial material layers 42 around each contact via cavity 85 selective to the insulating layers 32 and the retro-stepped dielectric material portions (165, 265, 365). For example, if the sacrificial material layers 42 comprise silicon nitride and if the retro-stepped dielectric material portions (165, 265, 365) comprises silicon oxide, the first isotropic etch process may comprise a wet etch process employing hot phosphoric acid which etches silicon nitride selective to silicon oxide materials. The duration of the first isotropic etch process can be selected such that the lateral recess distance of the first isotropic recess etch process is in a range from 100 % to 1,000 %, such as from 200 % to 500 %, of the thickness of unthickened portions of the sacrificial material layers 42. For each contact via cavity 85 that vertically extends through at least one unthickened portion of the sacrificial material layers 42, at least one first annular recess region 21 may be formed in volumes from which material portions of sacrificial material layers 42 are removed selectively to the insulating layers 32. For each contact via cavity 85, a second annular recess region 23 can be formed by isotropically etching a proximal region of a thickened portion of a respective sacrificial material layer 23 selective to the insulating layers 32. Each contact via cavity 85 is laterally expanded at one or more levels of the sacrificial material layers 42 through formation of the annular recess regions (21, 23), and is converted into a respective laterally-expanded contact via cavity 83.

Referring to FIG. 17, a recess-fill dielectric material layer (not shown) can be formed by conformally depositing a recess-fill dielectric material, such as silicon oxide, in the first annular recess regions 21 and the second annular recess regions 23, and over sidewalls of the laterally-expanded contact via cavities 83 (i.e., contact via cavities 85 as laterally expanded by the first isotropic etch process). The thickness of the recess-fill dielectric material layer can be greater than one half of the thickness of the unthickened portions of the sacrificial material layers 42, and can be less than one half of the thickness of the thickened portions of the sacrificial material layers 42. Thus, each first annular recess region 21 is completely filled with the recess-fill dielectric material layer, while each second annular recess region 23 is only partly filled by the recess-fill dielectric material layer.

A second isotropic etch process can be performed to isotropically etch the material of the recess-fill dielectric material layer. For example, the second isotropic etch process may comprise a wet etch process employing dilute hydrofluoric acid, such as 100:1 dilute hydrofluoric acid. According to an aspect of the present disclosure, the duration of the second isotropic etch process can be selected to ensure removal of the entirety of each portion of the recess-fill dielectric material layer that fills the second annular recess regions 23 of the laterally-expanded contact via cavities 83. In one embodiment, the duration of the second isotropic etch process can be selected such that the recess etch distance of the second isotropic etch process for the material of the recess-fill dielectric material layer is in a range from 105 % to 150 %, such as from 100 % to 130 %, of the thickness of the recess-fill dielectric material layer.

The second isotropic etch process removes the recess-fill dielectric material layer from an entire volume of each second annular recess region 23. Thus, the recess-fill dielectric material layer is entirely removed from each second annular recess region 23. Each remaining portion of the recess-fill dielectric material layer that fills a respective one of the first annular recess regions 21 comprises an annular dielectric spacer 26. Thus, each first annular recess region 21 is filled within a respective annular dielectric spacer 26. For each contact via cavity 85 that vertically extends through three or more sacrificial material layers 42, a vertical stack of annular dielectric spacers 26 can be formed around the contact via cavity 85. In other words, for each laterally-expanded contact via cavity 83 that vertically extends through three or more sacrificial material layers 42, a vertical stack of annular dielectric spacers 26 can fill two or more first annular recess regions 21. For each contact via cavity 85 that vertically extends through a plurality of sacrificial material layers 42, each unthickened annular portion of the plurality of sacrificial material layers 42 around the contact via cavity 85 can be replaced with a respective annular dielectric spacer 26. Thus, the annular dielectric spacers 26 are formed within a subset of the annular recess regions (21, 23), i.e., within the first annular recess regions 21.

Referring to FIG. 18, a sacrificial fill material can be deposited within volumes of the laterally-expanded contact via cavities 83 that are not filled with the annular dielectric spacers 26. The sacrificial fill material may comprise any material that is different from the materials of the insulating layers 32 and the sacrificial material layers 42. For example, the sacrificial fill material may comprise a semiconductor material, organosilicate glass, a polymer material, a photoresist material, or any other sacrificial material that may be subsequently removed selective to materials of the insulating layers 32, the retro-stepped dielectric material portions (165, 265, 365), and electrically conductive layers to be subsequently formed. Excess portions of the sacrificial fill material may be removed from above the horizontal plane including the top surface of the contact-level dielectric layer 80. Each remaining portion of the sacrificial fill material that fills a respective one of the laterally-expanded contact via cavities 83 constitutes a sacrificial through-via structure 84.

Each sacrificial through-via structure 84 is in direct contact with a cylindrical sidewall of a thickened portion of a respective one of the sacrificial material layers 42, and may optionally vertically extend through one or more additional sacrificial material layers 42. Each sacrificial through-via structure 84 is in contact with at least one of the first-tier retro-stepped dielectric material portion 165, the second-tier retro-stepped dielectric material portion 265, and the third-tier retro-stepped dielectric material portion 365. Each sacrificial through-via structure 84 that vertically extends through at least one opening through at least one unthickened portion of the sacrificial material layers 42 is laterally surrounded by, and is contacted by, one or more of the annular dielectric spacers 26. A subset of the sacrificial through-via structures 84 can be laterally surrounded by a respective set of at least one annular dielectric spacer 26. In one embodiment, a subset of the sacrificial through-via structures 84 can be laterally surrounded by a respective vertical stack of annular dielectric spacers 26.

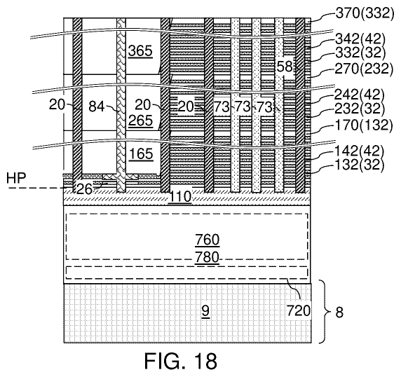

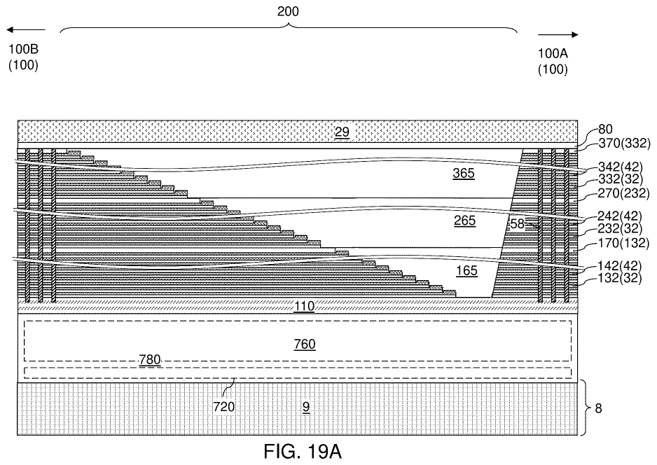

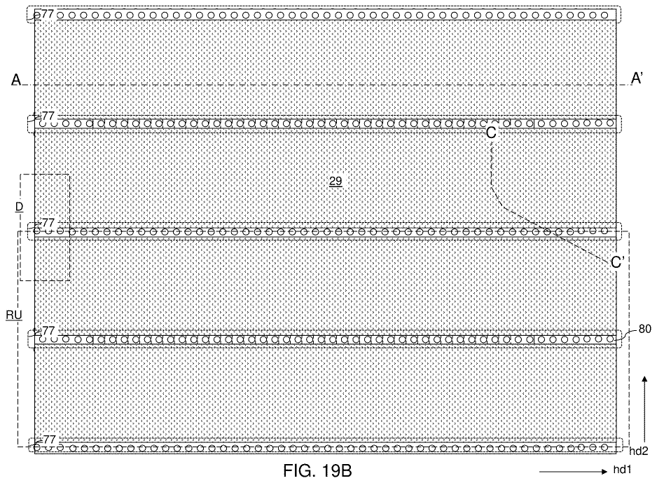

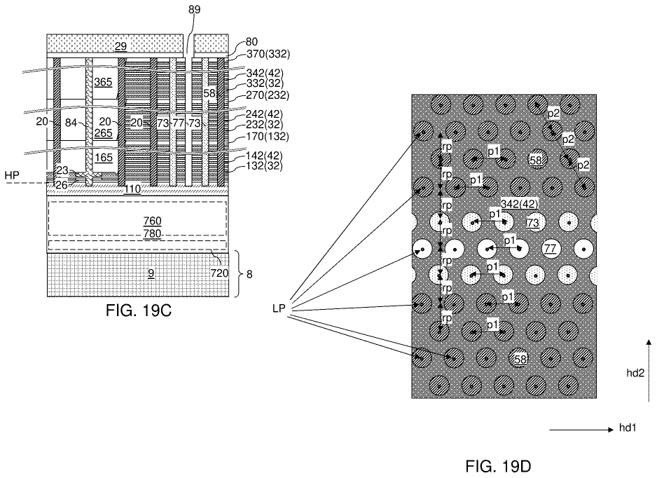

Referring to FIG. 19A-19D, a contact-level dielectric layer 80 can be deposited over the third-tier insulating cap layer 370 and the third-tier retro-stepped dielectric material portions 365. The contact-level dielectric layer 80 comprises a dielectric material, such as silicon oxide, and may have a thickness in a range from 100 nm to 800 nm, although lesser and greater thicknesses may also be employed.

A second photoresist layer 29 can be applied over the contact-level dielectric layer 80, and can be lithographically patterned to form elongated openings over the areas of the sacrificial isolation opening fill structures 73. According to an aspect of the present disclosure, each neighboring cluster of memory opening fill structures 58 spaced along the second horizontal direction hd2 may comprise a respective set of three rows of sacrificial isolation opening fill structures 73. Each elongated opening in the second photoresist layer 29 may have an areal overlap with a middle row of the sacrificial isolation opening fill structures 73 (which is located within the volumes of a respective row of isolation openings 77) within a respective set of three rows of the sacrificial isolation opening fill structures 73, and does not have any areal overlap with two peripheral rows of the sacrificial isolation opening fill structures 73 within the respective set of three rows of the sacrificial isolation opening fill structures 73.

An anisotropic etch process can be performed to transfer the pattern of the elongated openings in the second photoresist layer 29 through the contact-level dielectric layer 80. Connection trenches 89 are formed through the contact-level dielectric layer 80. Each connection trench 89 overlies a respective middle row of sacrificial isolation opening fill structures 73. A first subset (i.e., middle row) of the sacrificial isolation opening fill structures 73 can be physically exposed underneath a respective opening in the second photoresist layer 29, while a second subset (i.e., peripheral rows) of the sacrificial isolation opening fill structures 73 is covered with the second photoresist layer 29.

The sacrificial fill material of the middle row of sacrificial isolation opening fill structures 73 can be removed selectively to the materials of retro-stepped dielectric material portions (165, 265, 365), the insulating layers 32, and the sacrificial material layers 42 by performing a selective etch process. Voids are formed in the volumes of a first subset of the isolation openings 77 from which the first subset of the sacrificial isolation opening fill structures 73, while a second subset of the isolation openings 77 underlie the second photoresist layer 29 and is filled with the second subset of the sacrificial isolation opening fill structures 73. The voids within the first subset of the isolation openings 77 are herein referred to as isolation cavities 77, which may be discrete pillar shaped cavities.

Generally, the isolation cavities can be formed by removing a first subset of the sacrificial isolation opening fill structures 73 from a first subset of the isolation openings 77 without removing a second subset of the sacrificial isolation opening fill structures 73. The first subset of the isolation openings 77 may be arranged in rows laterally extending along the first horizontal direction hd1. A single row of sacrificial isolation opening fill structures 73 can be removed from a single row of isolation openings 77 between each pair of clusters of memory opening fill structures 58 that are spaced along the second horizontal direction hd2. In one embodiment, each row of isolation openings 77 containing a respective row of isolation cavities can be located between two rows of sacrificial isolation opening fill structures 73 of the remaining two peripheral rows of sacrificial isolation opening fill structures 73. In one embodiment, for each middle row of isolation openings 77, geometrical centers of the two peripheral rows of sacrificial isolation opening fill structures 73 are located at most proximal lattice points LP from lattice points LP located at geometrical centers of the middle row of isolation openings 77 in the horizontal cross-sectional view.

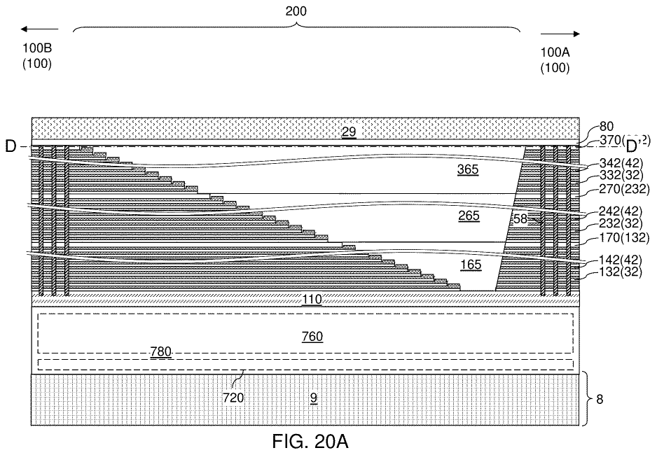

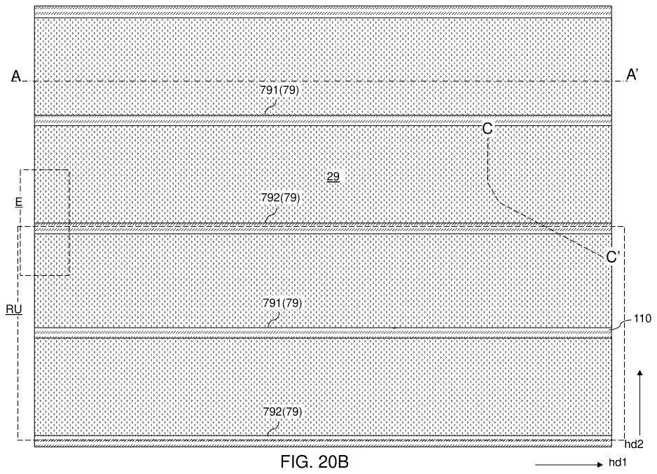

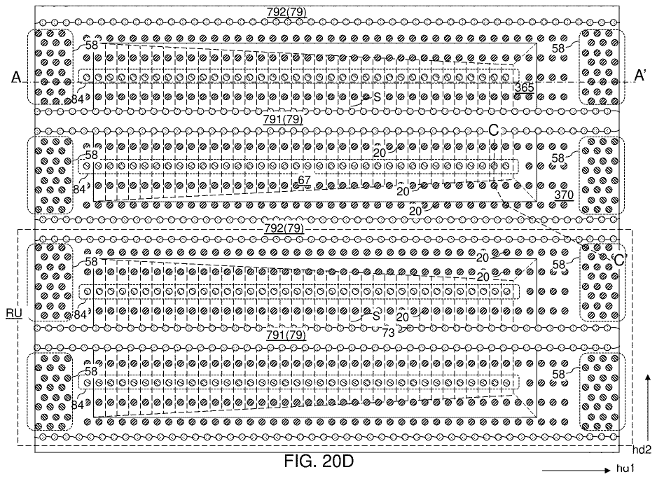

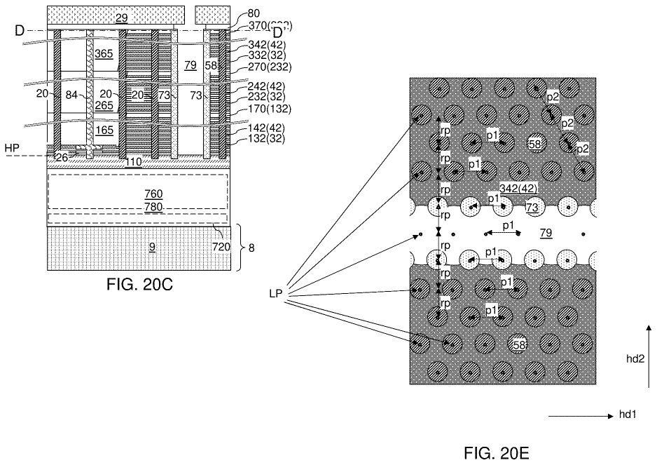

Referring to FIG. 20A-20D, at least one selective isotropic etch process can be performed to isotropically recess the materials of the insulating layers 32, the sacrificial material layers 42, and the retro-stepped dielectric material portions (165, 265, 365) selective to the materials of the semiconductor material layer 110 and the sacrificial isolation opening fill structures 73. For example, the at least one selective isotropic etch process may comprise a combination of a first selective isotropic etch process that etches the materials of the insulating layers 32 and the retro-stepped dielectric material portions (165, 265, 365) selectively to the materials of the semiconductor material layer 110 and the sacrificial isolation opening fill structures 73; and a second selective isotropic etch process that etches the material of the sacrificial material layers 42 selectively to the materials of the semiconductor material layer 110 and the sacrificial isolation opening fill structures 73. In an illustrative example, the insulating layers 32 and the retro-stepped dielectric material portions (165, 265, 365) may comprise silicon oxide material and the first isotropic etch process may comprise a wet etch process employing dilute hydrofluoric acid, and the sacrificial material layers 42 may comprise silicon nitride and the second isotropic etch process may comprise a wet etch process employing hot phosphoric acid.

According to an aspect of the present disclosure, the duration(s) of the at least one selective isotropic etch process may be selected such that the isolation cavities 77 merge among one another along the first horizontal direction hd1. Each continuous merged cavity formed by merging of the expanded isolation cavities from a same middle row of isolation openings 77 constitutes a lateral isolation trench 79. The at least one selective isotropic etch process is selective to the material of the sacrificial isolation opening fill structures 73, and the duration(s) of the at least one selective isotropic etch process may be selected such that each sacrificial isolation opening fill structure 73 has a respective first vertically-straight and horizontally-convex surface segment that is physically exposed to a respective one of the lateral isolation trenches 79, and a respective second vertically-straight and horizontally-convex surface segment that is in contact with a remaining portion of the vertically alternating sequence (32, 42). As used herein, a vertically-straight surface segment refers to a surface segment that extends along a vertical direction and having a straight vertical cross-sectional profile. As used herein, a horizontally-convex surface segment refers to a surface segment having a convex horizontal cross-sectional profile. As used herein, a horizontally-concave surface segment refers to a surface segment having a concave horizontal cross-sectional profile.

In one embodiment, the lateral isolation trenches 79 may comprise first-type lateral isolation trenches 791 that divide a respective row of first-tier retro-stepped dielectric material portions 165, a respective row of second-tier retro-stepped dielectric material portions 265, and a respective row of third-tier retro-stepped dielectric material portions 365 along the second horizontal direction hd2. Further, the lateral isolation trenches 79 may comprise second-type lateral isolation trenches 792 that do not intersect, and are laterally spaced from, the retro-stepped dielectric material portions (165, 265, 365). The patterning film can be subsequently removed, for example, by ashing or selective etching. The lateral isolation trenches 79 are laterally spaced from each of the contact via cavities 85. Optionally, an oxidation process may be performed to convert physically exposed surface portions of the semiconductor material layer 110 into semiconductor oxide trench liners (not illustrated).

Generally, the lateral isolation trenches 79 divide the vertically alternating sequence of continuous insulating layers 32 and continuous sacrificial material layers 42 into a respective plurality of alternating stacks (32, 42) of insulating layers 32 and sacrificial material layers 42. For the purpose of distinguishing layers in the first exemplary structure prior to formation of the lateral isolation trenches 79 from layers in the first exemplary structure after formation of the lateral isolation trenches 79, each insulating layer 32 prior to formation of the lateral isolation trenches 79 may be referred to as a continuous insulating layer 32. The continuous insulating layers 32 in the first exemplary structure prior to formation of the lateral isolation trenches 79 may comprise first-tier continuous insulating layers 132, second-tier continuous insulating layers 232, and third-tier continuous insulating layers 332. Likewise, each sacrificial material layer 42 prior to formation of the lateral isolation trenches 79 may be referred to as a continuous sacrificial material layer 42. The continuous sacrificial material layers 42 in the first exemplary structure prior to formation of the lateral isolation trenches 79 may comprise first-tier continuous sacrificial material layers 142, second-tier continuous sacrificial material layers 242, and third-tier continuous sacrificial material layers 342.

Thus, the first-tier alternating stack of first-tier continuous insulating layers 132 and first-tier sacrificial material layers 142 is divided into a plurality of alternating stacks of first-tier insulating layers 132 and first-tier sacrificial material layers 142. The second-tier alternating stack of second-tier continuous insulating layers 232 and second-tier sacrificial material layers 242 is divided into a plurality of alternating stacks of second-tier insulating layers 232 and second-tier sacrificial material layers 242. The third-tier alternating stack of third-tier continuous insulating layers 332 and third-tier sacrificial material layers 342 is divided into a plurality of alternating stacks of third-tier insulating layers 332 and third-tier sacrificial material layers 342.

A vertical stack of a first-tier alternating stack (132, 142), a second-tier alternating stack (232, 242), and a third-tier alternating stack (332, 342) is formed between each neighboring pair of lateral isolation trenches 79. In some cases, the vertical stack may be referred to as an alternating stack of insulating layers 32 and sacrificial material layers 42, in which the distinction among the different tier structures is ignored. Each vertical stack of a first-tier alternating stack (132, 142), a second-tier alternating stack (232, 242), and a third-tier alternating stack (332, 342) embeds a first-tier retro-stepped dielectric material portion 165, a second-tier retro-stepped dielectric material portion 265, and a third-tier retro-stepped dielectric material portion 365. Each first-tier retro-stepped dielectric material portion 165 may comprise a respective lengthwise sidewall that is parallel to the first horizontal direction hd1 and is exposed to a respective first-type lateral isolation trench 791. Each second-tier retro-stepped dielectric material portion 265 may comprise a respective lengthwise sidewall that is parallel to the first horizontal direction hd1 and is exposed to a respective second-type lateral isolation trench 792. Each third-tier retro-stepped dielectric material portion 365 may comprise a respective lengthwise sidewall that is parallel to the first horizontal direction hd1 and is exposed to a respective second-type lateral isolation trench 792. In one embodiment, each retro-stepped dielectric material portion (165, 265, 365) is not in direct contact with any other retro-stepped dielectric material portion (165, 265, 365).

A vertical stack of a first-tier structure, a second-tier structure, and a third-tier structure can be formed between each laterally neighboring pair of lateral isolation trenches 79. The vertical stack of the first-tier structure, the second-tier structure, and the third-tier structure constitutes a multi-tier structure (e.g., a memory block). The first-tier structure is located over the semiconductor material layer 110 and comprises a respective first-tier alternating stack (132, 142) of first-tier insulating layers 132 and first-tier sacrificial material layers 142. The second-tier structure (232, 242, 265) overlies the first-tier structure (132, 142, 165) and includes a second-tier alternating stack (232, 242) of second-tier insulating layers 232 and second-tier sacrificial material layers 242. The third-tier structure (332, 342, 365) overlies the second-tier structure (232, 242, 265) and includes a third-tier alternating stack (332, 342) of third-tier insulating layers 332 and third-tier sacrificial material layers 342.

Each multi-tier structure embeds a respective set of retro-stepped dielectric material portions (165, 265, 365), which includes a first-tier retro-stepped dielectric material portion 165, a second-tier retro-stepped dielectric material portion 265, and a third-tier retro-stepped dielectric material portion 365. The first exemplary structure comprises a plurality of multi-tier structures located over a semiconductor layer (such as a semiconductor material layer within the semiconductor material layer 110) and laterally spaced apart from each other by a plurality of lateral isolation trenches 79 that laterally extend along a first horizontal direction hd1.

Each lateral isolation trench 79 comprises a respective pair of lengthwise sidewalls that generally extend along the first horizontal direction hd1 with lateral undulations along the second horizontal direction hd2. In one embodiment, each lengthwise sidewall of the lateral isolation trenches 79 may comprise a periodic repetition of vertically-straight and horizontally-convex surfaces of a respective row of sacrificial isolation opening fill structures 73, which are periodic surfaces having the periodicity of the first pitch p1 along the first horizontal direction hd1. Further, each lengthwise sidewall of the lateral isolation trenches 79 may comprise a respective row of connecting surface segments that are interlaced with the periodic repetition of vertically-straight and horizontally-convex surfaces of the respective row of sacrificial isolation opening fill structures 73. The respective row of connecting surface segments may comprise vertically-straight and horizontally-concave surface segments of a respective alternating stack (32, 42) of insulating layers 32 and sacrificial material layers 42. In one embodiment, the vertically-straight and horizontally-convex surface segments of the alternating stacks (32, 42) may have a radius of curvature that is greater than a difference between the first pitch p1 and a radius of a horizonal cross-sectional shape of each of the memory openings 49, and is less than a sum of the first pitch p1 and the radius of the horizonal cross-sectional shape of each of the memory openings 49.

The lateral isolation trenches 79 have lateral undulations in width, and as such, may be referred to as laterally-undulating lateral isolation trenches 79. In summary, the laterally-undulating lateral isolation trenches 79 may be formed through the vertically alternating sequence (32, 42) by performing at least one isotropic etch process that etches materials of the vertically alternating sequence (32, 42) around a subset of isolation openings 77. The at least one isotropic etch process etches the materials of the vertically alternating sequence (32, 42) selectively to a material of the second subset of the sacrificial isolation opening fill structures 73. The vertically alternating sequence (32, 42) is divided into multiple alternating stacks (32, 42) of respective insulating layers 32 and respective sacrificial material layers 42 that are laterally spaced apart by the laterally-undulating lateral isolation trenches 79.

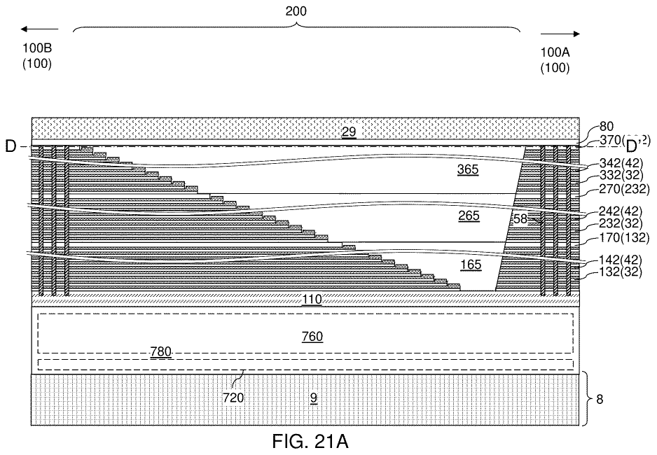

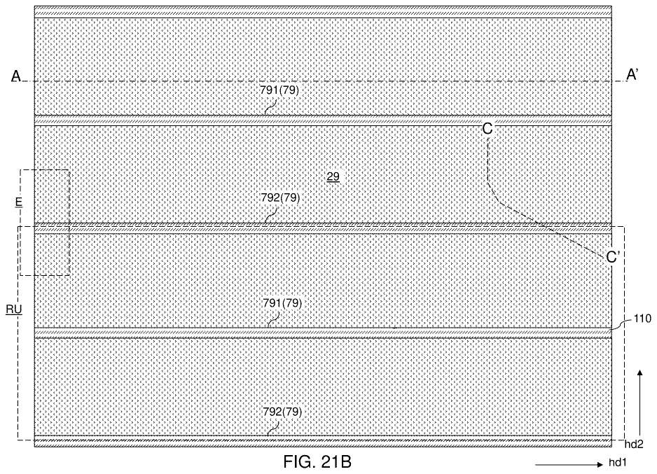

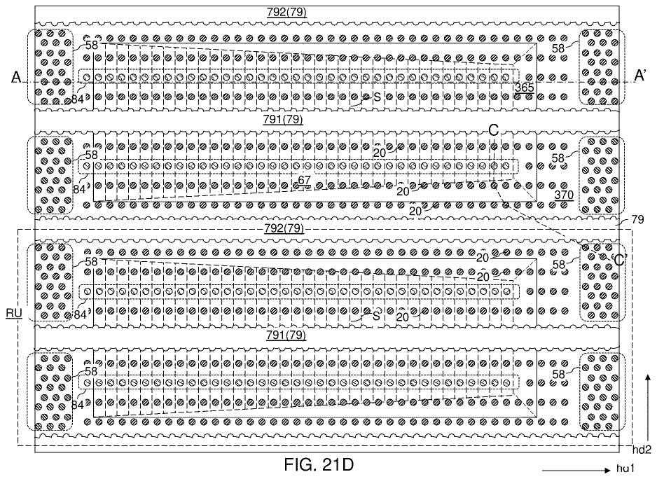

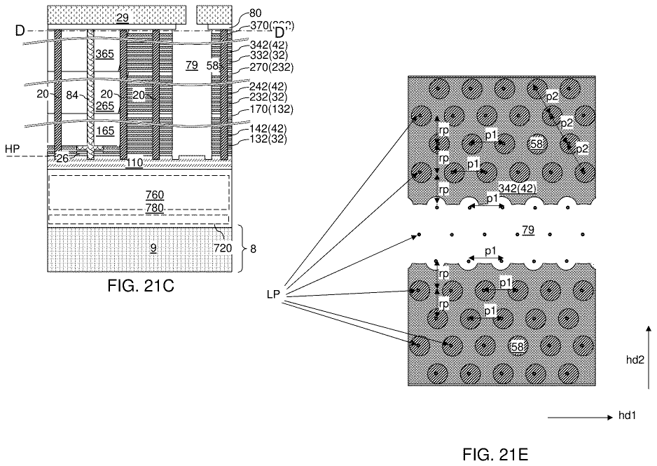

Referring to FIG. 21A-21E, an additional selective isotropic etch process may be optionally performed to remove the second subset (i.e., the peripheral rows) of the sacrificial isolation opening fill structures 73 selectively to the materials of the insulating layers 32, the sacrificial material layers 42, the retro-stepped dielectric material portions (165, 265, 365), and the semiconductor material layer 110. The lateral isolation trenches 79 are laterally expanded upon removal of the second subset of the sacrificial isolation opening fill structures 73. In this case, each lengthwise sidewall of the lateral isolation trenches 79 comprises a respective row of lateral indentations defined by vertically-straight and horizontally-concave surface segments of a respective alternating stack (32, 42) of insulating layers 32 and sacrificial material layers 42 (i.e., the horizontally-concave surface segments of a respective alternating stack (32, 42) correspond to horizontally-convex protrusions of the lateral isolation trench 79 into the alternating stack (32, 42)). Further, each lengthwise sidewall of the lateral isolation trenches 79 may comprise a respective row of connecting surface segments of the respective alternating stack (32, 42) that are interlaced with the periodic repetition of vertically-straight and horizontally-concave surfaces of the respective alternating stack (32, 42).

In one embodiment, the vertically-straight and horizontally-convex surface segments of the connecting surfaces may have a radius of curvature that is greater than a difference between the first pitch p1 and a radius of a horizonal cross-sectional shape of each of the memory openings 49, and is less than a sum of the first pitch p1 and the radius of the horizonal cross-sectional shape of each of the memory openings 49. In one embodiment, the vertically-straight and horizontally-concave surface segments of a respective alternating stack (32, 42) within the lateral indentations may have a radius of curvature that equals the radius of each sacrificial isolation opening fill structure 73 prior to removal of the sacrificial isolation opening fill structures 73.

Thus, the multi-step formation of the lateral isolation trenches 79 avoids or reduces bending of the outer row of the memory opening fill structures 58 due to a difference in mask (e.g., photoresist layer) height between the memory array regions (100A, 100B) and the contact region 200. Furthermore, by using at least three rows of isolation openings 77, the likelihood of electrical shorts between adjacent memory blocks due to failure to connect laterally adjacent isolation openings 77 along the first horizontal direction hd1 is reduced. Thus, the margin of the wet etch used to form the lateral isolation trenches 79 is expanded, and the lateral isolation trenches 79 are continuous along the first horizontal direction even if one of the middle row isolation openings 77 unintentionally remains filled with the respective sacrificial isolation opening fill structure 73.

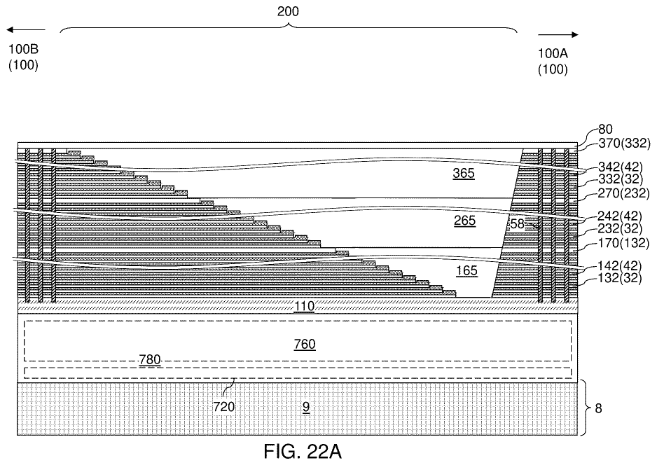

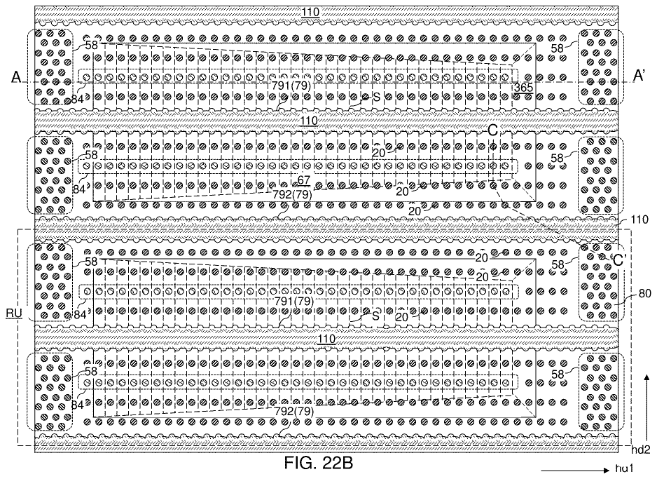

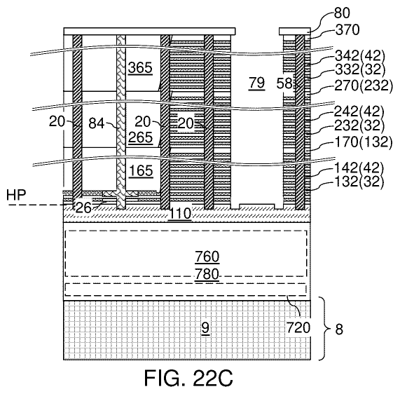

Referring to FIG. 22A-22C, the second photoresist layer 29 may be removed, for example, by ashing.

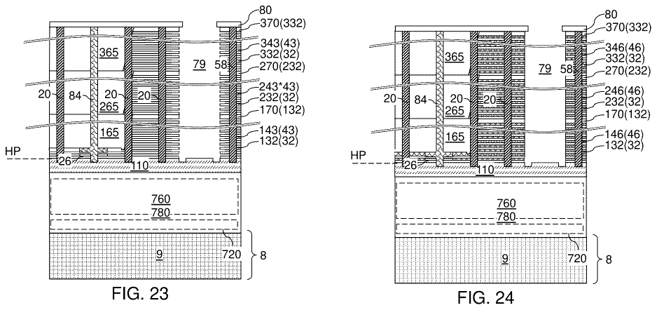

Referring to FIG. 23, laterally-extending cavities 43 can be formed by selective removal of the sacrificial material layers 42. A selective etch process can be performed to remove the sacrificial material layers 42 selectively to the insulating layers 32 employing the lateral isolation trenches 79 as conduits for transporting an isotropic etchant of the selective etch process. Specifically, the sacrificial material layers 42 may be isotropically etched selective to the insulating layers 32, the annular dielectric spacers 26, and the retro-stepped dielectric material portions (165, 265, 365) by supplying an isotropic etchant into the lateral isolation trenches 79 and into the contact via cavities 85. In one embodiment, an etchant that selectively etches the materials of the sacrificial material layers 42 with respect to the materials of the insulating layers 32, the annular dielectric spacers 26, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the annular dielectric spacers 26, the retro-stepped dielectric material portions (165, 265, 365), and the outermost layer of the memory films 50 comprise silicon oxide materials, the etch process may comprise a hot phosphoric acid etch process, which etches silicon nitride selective to silicon oxide, silicon, and various other materials used in the art.

The laterally-extending cavities 43 are formed in volumes from which the sacrificial material layers 42 are removed. The laterally-extending cavities 43 include first-tier laterally-extending cavities 143 that are formed in volumes from which the first-tier sacrificial material layers 142 are removed, second-tier laterally-extending cavities 243 that are formed in volumes from which the second-tier sacrificial material layers 242 are removed, and third-tier laterally-extending cavities 343 that are formed in volumes from which the third-tier sacrificial material layers 342 are removed. Each of the laterally-extending cavities 43 may be a laterally extending cavity having a greater lateral dimension that is greater than a vertical extent. In other words, the lateral dimension of each of the laterally-extending cavities 43 may be greater than the height of the respective laterally-extending cavity 43. A plurality of laterally-extending cavities 43 may be formed in the volumes from which the material of the sacrificial material layers 42 is removed. Each of the laterally-extending cavities 43 may extend substantially parallel to the top surface of the semiconductor material layer 110. A laterally-extending cavity 43 may be vertically bounded by a top surface of an underlying insulating layer 32 and a bottom surface of an overlying insulating layer 32.

Referring to FIG. 24, an outer blocking dielectric layer (not expressly shown) may be conformally deposited in peripheral portions of the laterally-extending cavities 43, the contact via cavities 85, and the lateral isolation trenches 79. The outer blocking dielectric layer includes a dielectric material, such as a dielectric metal oxide (e.g., aluminum oxide), silicon oxide, or a combination thereof. The outer blocking dielectric layer may be formed as a continuous material layer having a uniform thickness throughout by a conformal deposition process such as an atomic layer deposition process and/or a chemical vapor deposition process. The thickness of the outer blocking dielectric layer may be in a range from 2 nm to 10 nm, such as from 3 nm to 8 nm, although lesser and greater thicknesses may also be employed.

A continuous electrically conductive material layer (not illustrated) may be deposited over the outer blocking dielectric layer to fill remaining volumes of the laterally-extending cavities 43, peripheral portions of the lateral isolation trenches 79, and peripheral portions of the contact via cavities 85. The lateral isolation trenches 79 are used conduits for transporting the reactants (e.g., CVD or ALD reactants) to the volumes of the laterally-extending cavities 43. In one embodiment, the continuous electrically conductive material layer may comprise a continuous metallic barrier liner layer (not expressly shown) and a continuous metal fill material layer (not expressly shown).

Specifically, a continuous metallic barrier liner layer may be conformally deposited on the physically exposed surfaces of the outer blocking dielectric layer in peripheral portions of the laterally-extending cavities 43 and the lateral isolation trenches 79. The continuous metallic barrier liner layer comprises a metallic diffusion barrier material. For example, the continuous metallic barrier liner layer may comprise and/or may consist essentially of a conductive metal nitride material, such as TiN, TaN, WN, and/or MoN. The continuous metallic barrier liner layer may be formed as a continuous material layer having a uniform thickness throughout by a conformal deposition process such as an atomic layer deposition process and/or a chemical vapor deposition process. The thickness of the continuous metallic barrier liner layer may be in a range from 1.5 nm to 8 nm, such as from 3 nm to 6 nm, although lesser and greater thicknesses may also be employed. In one embodiment, the continuous metallic barrier liner layer extends continuously over the entirety of the outer blocking dielectric layer as a single continuous material layer.

The continuous metal fill material layer may be conformally deposited on the physically exposed surfaces of the continuous metallic barrier liner layer in remaining unfilled volumes of the laterally-extending cavities 43 and in peripheral regions of the lateral isolation trenches 79. The continuous metal fill material layer comprises a metal fill material that provides high electrical conductivity. For example, the continuous metal fill material layer comprises and/or consists essentially of an elemental metal such as W, Co, Ru, Mo, Cu, or a combination thereof. The continuous metal fill material layer may be formed by a conformal deposition process, such as a chemical vapor deposition (CVD) process or an atomic layer deposition (ALD) process. The lateral isolation trenches 79 may be used as conduits for the reactant that deposits the continuous metal fill material layer. In one embodiment, the continuous metal fill material layer extends continuously over the entirety of the continuous metallic barrier liner layer as a single continuous material layer.

The combination of the outer blocking dielectric layer, the continuous metallic barrier liner layer, and the continuous metal fill material layer fill the entirety of the laterally-extending cavities 43, and fill peripheral portions of the lateral isolation trenches 79. Generally, at least one conformal deposition process can be performed after formation of the outer blocking dielectric layer to deposit at least one first electrically conductive material of the electrically conductive material layer in remaining volumes of the laterally-extending cavities 43, and in an elongated tubular regions of each lateral isolation trench 79. Each portion of the continuous electrically conductive material layer that replaces an unthickened portion of the sacrificial material layers 42 may have a first thickness, and each portion of the continuous electrically conductive material layer that replace a thickened portion of the sacrificial material layers 42 may have a second thickness which is greater than the first thickness.

A selective etch process can be performed to etch portions of the continuous electrically conductive material layer from inside the lateral isolation trenches 79. Each remaining portion of the combination of the continuous metallic barrier liner layer and the continuous metal fill material layer that fills a respective laterally-extending cavity 43 constitutes an electrically conductive layer 46. The electrically conductive layers 46 comprise first-tier electrically conductive layers 146 that are formed in the first-tier laterally-extending cavities 143, second-tier electrically conductive layers 246 that are formed in the second-tier laterally-extending cavities 243, and third-tier electrically conductive layers 346 that are formed in the third-tier laterally-extending cavities 343. First-tier alternating stacks (132, 246) of first-tier insulating layers 132 and first-tier electrically conductive layers 146 are formed within the first-tier structure, second-tier alternating stacks (132, 246) of second-tier insulating layers 232 and second-tier electrically conductive layers 246 are formed within the second-tier structure, and third-tier alternating stacks (132, 246) of third-tier insulating layers 332 and third-tier electrically conductive layers 346 are formed within the third-tier structure.

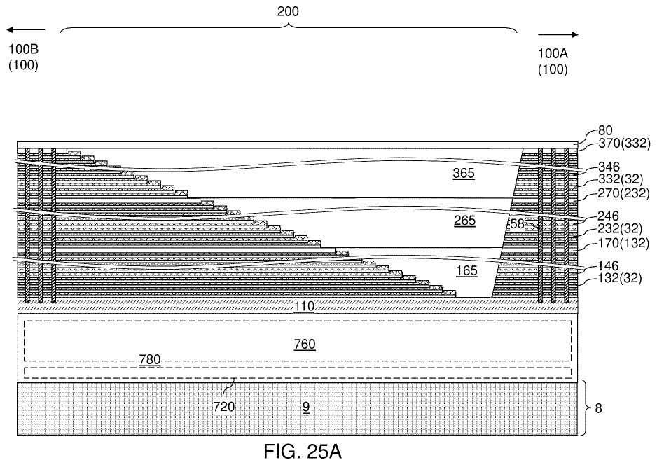

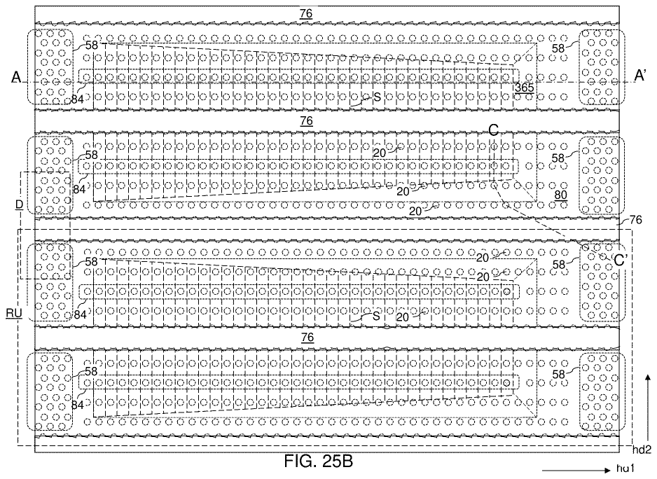

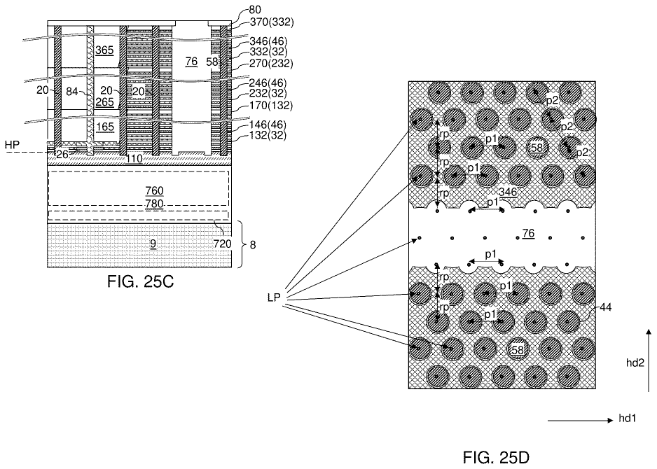

Referring to FIG. 25A-25D, a dielectric fill material, such as undoped silicate glass or a doped silicate glass, can be deposited in the lateral isolation trenches 79 by a conformal deposition process. Excess portions of the dielectric fill material may be removed from above the horizontal plane including the top surface of the contact-level dielectric layer 80 by a planarization process, which may comprise a recess etch process and/or a chemical mechanical polishing process. Each remaining portion of the dielectric fill material that fills a respective one of the lateral isolation trenches 79 constitute a lateral isolation trench fill structure 76. The lateral isolation trench fill structures 76 may comprise first-type lateral isolation trench fill structures 761 that are formed in the first-type lateral isolation trenches 791 and second-type lateral isolation trench fill structures 762 that are formed in the second-type lateral isolation trenches 792.

A plurality of lateral isolation trench fill structures 76 can be formed in the plurality of lateral isolation trenches 79. Each multi-tier structure within the plurality of multi-tier structures comprises a first lengthwise sidewall that is parallel to the first horizontal direction hd1 and contacting a respective one of the lateral isolation trench fill structures 76 and a second lengthwise sidewall that is parallel to the first horizontal direction hd1 and contacting a respective additional one of the lateral isolation trench fill structures 76.

The first exemplary structure comprises a semiconductor structure which comprises: alternating stacks (32, 46) of insulating layers 32 and electrically conductive layers 46, wherein each of the alternating stacks (32, 46) laterally extends along a first horizontal direction hd1, wherein the alternating stacks (32, 46) are laterally spaced apart from each other along a second horizontal direction hd2 by lateral isolation trench fill structures 76 that laterally extend along the first horizontal direction hd1; memory openings 49 vertically extending through a respective one of the alternating stacks (32, 46); and memory opening fill structures 58 located in a respective one of the memory openings 49 and comprising a respective vertical semiconductor channel 60 and a respective vertical stack of memory elements (e.g., portions of the memory film 50) located at levels of the electrically conductive layers 46, wherein the memory opening fill structures 58 are arranged in rows each laterally extending along the first horizontal direction hd1 with a memory opening 49 periodicity having a first pitch p1. Each of the lateral isolation trench fill structures 76 comprises a respective pair of lengthwise sidewalls, wherein each of the lengthwise sidewalls laterally extends generally along the first horizontal direction hd1 and comprises respective lateral undulations along a second horizontal direction hd2 that is perpendicular to the first horizontal direction hd1, the respective lateral undulations having an undulation periodicity that equals the first pitch p1. Geometrical centers of the memory opening fill structures 58 and centers of curvature of the lateral undulations of the lateral isolation trench fill structures 76 are located at lattice points LP of a two-dimensional periodic array in a horizontal cross-sectional view.

In one embodiment, the two-dimensional periodic array comprises a hexagonal array having a first periodicity direction along the first horizontal direction hd1. In one embodiment, the alternating stacks (32, 46) comprise three or more alternating stacks (32, 46), and all geometrical centers of the memory opening fill structures 58 located within the three or more alternating stacks (32, 46) are located at a subset of the lattice points LP of the two-dimensional periodic array.

In one embodiment, each of the lateral isolation trench fill structure 76 comprises exactly three rows of lattice points LP arranged along the first horizontal direction hd1 within the two-dimensional periodic array in the horizontal cross-sectional view. In one embodiment, the centers of curvature of the lateral undulations are located entirely within the lateral isolation trench fill structures 76 in the horizontal cross-sectional view.

In one embodiment, each of the lengthwise sidewalls of the lateral isolation trench fill structures 76 comprises a respective set of vertically-straight connecting surface segments that are interlaced with, and adjoined to, the respective lateral undulation. In one embodiment, the respective set of vertically-straight connecting surface segments comprise horizontally-convex surface segment having a radius of curvature that is greater than a difference between the first pitch p1 and a radius of a horizonal cross-sectional shape of each of the memory openings 49, and is less than a sum of the first pitch p1 and the radius of the horizonal cross-sectional shape of each of the memory openings 49.

According to another aspect of the present disclosure, a semiconductor structure is provided, which comprises: alternating stacks (32, 46) of insulating layers 32 and electrically conductive layers 46, wherein each of the alternating stacks (32, 46) laterally extends along a first horizontal direction hd1, wherein the alternating stacks (32, 46) are laterally spaced apart from each other along a second horizontal direction hd2 by lateral isolation trench fill structures 76 that laterally extend along the first horizontal direction hd1; memory openings 49 vertically extending through a respective one of the alternating stacks (32, 46); and memory opening fill structures 58 located in a respective one of the memory openings 49, wherein the memory opening fill structures 58 are arranged in rows each laterally extending along the first horizontal direction hd1 with a memory opening 49 periodicity having a first pitch p1. Each of the lateral isolation trench fill structures 76 comprises a respective pair of lengthwise sidewalls, wherein each of the lengthwise sidewalls laterally extends generally along the first horizontal direction hd1 and comprises respective lateral undulations along a second horizontal direction hd2 that is perpendicular to the first horizontal direction hd1, the respective lateral undulations having an undulation periodicity that equals the first pitch p1. The respective lateral undulations comprise vertically-straight and horizontally oval-arc-shaped surface segment in direct contact with vertically-straight and horizontally-concave surface segments of electrically conductive layers 46 of a respective alternating stack (32, 46). Each of the lengthwise sidewalls of the lateral isolation trench fill structures 76 comprises a respective set of vertically-straight connecting surface segments that are interlaced with and adjoined to the respective lateral undulation.

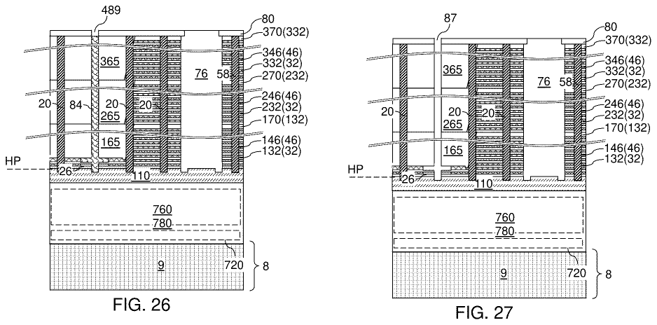

Referring to FIG. 26, connection via cavities 489 can be formed though the contact-level dielectric layer 80 over the sacrificial through-via structures 84. Each top surface of the sacrificial through-via structures 84 may be physically exposed underneath a respective one of the connection via cavities 489.

Referring to FIG. 27, a selective etch process may be performed to remove sacrificial through-via structures 84 selective to the materials of the contact-level dielectric layer 80, the retro-stepped dielectric material portions (165, 265, 365), the insulating layers 32, and the electrically conductive layers 46. Through-via cavities 87 can be formed in the volumes from which the sacrificial through-via structures 84 are removed. An isotropic etch process may be performed to remove any physically exposed portion of the outer blocking dielectric layers (not shown) from around the through-via cavities 87. Each through-via cavity 87 is a contact via cavity to which a surface of a respective electrically conductive layer 46 is physically exposed. In one embodiment, each through-via cavity 87 comprises a respective annular recess region to which a cylindrical sidewall of a respective electrically conductive layer 46 is physically exposed.

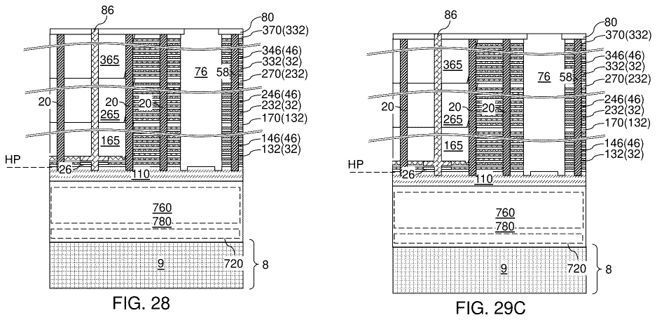

Referring to FIG. 28, at least one metallic material, such as a combination of a metallic barrier liner material and a metallic fill material, can be conformally deposited in the through-via cavities 87 directly on physically exposed surface segments of the electrically conductive layers 46. Excess portions of the at least one metallic material may be removed from above the horizontal plane including the top surface of the contact-level dielectric layer 80 by a planarization process, which may comprise a recess etch process and/or a chemical mechanical polishing process. Each remaining portion of the at least one metallic material filling a respective one of the through-via cavities 87 constitute a through-via contact structure 86.

Each through-via contact structure 86 vertically extends through a respective retro-stepped dielectric material portion (165, 265, or 365) and a set of at least one electrically conductive layer 46 located within a same tier structure as the respective retro-stepped dielectric material portion (165, 265, or 365) or underlies the respective retro-stepped dielectric material portion (165, 265, or 365). Each through-via contact structure 86 is electrically connected to, and is in direct contact with, a topmost electrically conductive layer 46 within the set of at least one electrically conductive layer 46. If the set of at least one electrically conductive layer 46 comprises a plurality of electrically conductive layers 46, the through-via contact structure 86 is laterally spaced from, and is electrically isolated from, each electrically conductive layer 46 within the set except the topmost electrically conductive layer 46 within the set by at least one annular dielectric spacer 26.

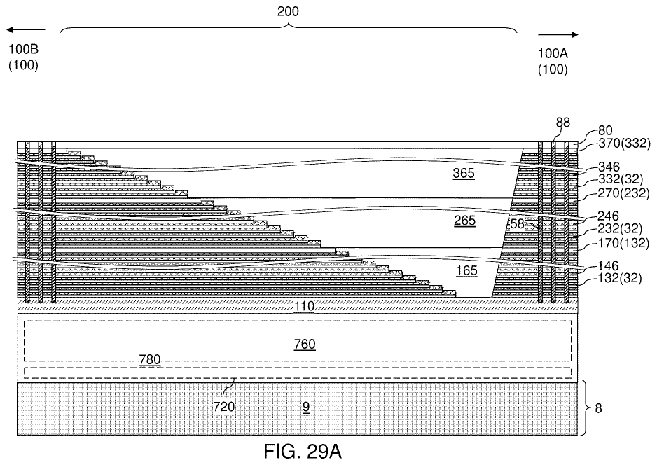

Referring to FIG. 29A-29C, drain contact via structures 88 can be formed through the contact-level dielectric layer 80 on the drain regions 63 within the memory opening fill structures 58. Each drain region 63 may be contacted by a respective one of the drain contact via structures 88.

Subsequently, additional dielectric material layers and additional metal interconnect structures can be formed over the contact-level dielectric layer 80. The first exemplary structure includes a two-dimensional periodic array of memory dies. The first exemplary structure may be bonded to another wafer including a respective two-dimensional periodic array of semiconductor dies, which may comprise logic dies or additional memory dies. A dicing process may be subsequently performed. Alternatively, the two-dimensional periodic array of memory dies may be diced without bonding to another wafer.

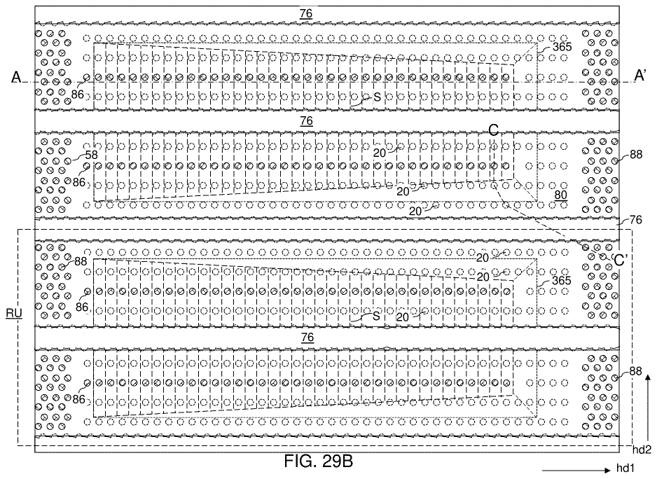

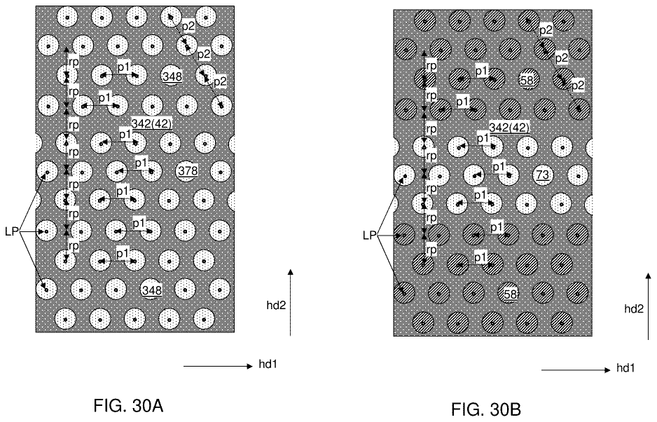

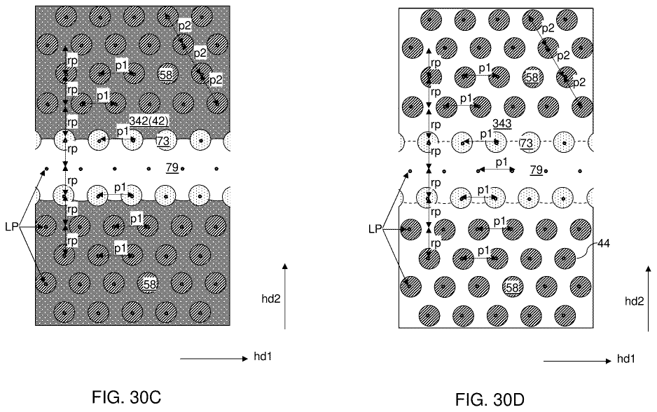

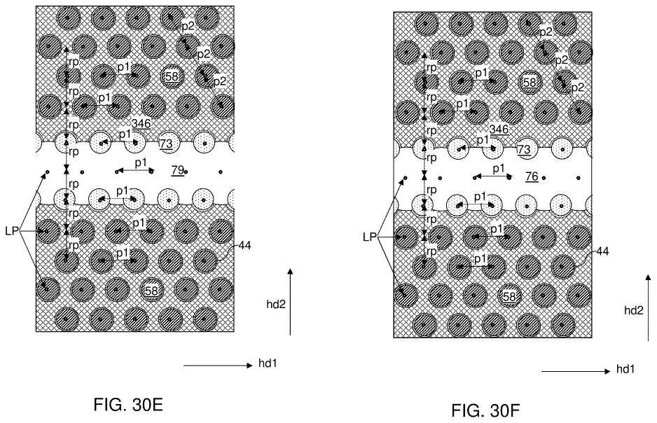

FIG. 30A-30F are various horizontal cross-sectional views of a second exemplary structure at a level of a third sacrificial material layer 42 or a third electrically conductive layer 46 according to an embodiment of the present disclosure. The second exemplary structure may be derived from the first exemplary structure described above by modifying the sequence of processing steps for forming the first exemplary structure.

Referring to FIG. 30A, a horizontal cross-sectional view of a region of the second exemplary structure is illustrated at the processing step described with reference to FIG. 7A 7D. Referring to FIG. 30B, a horizontal cross-sectional view of a region of the second exemplary structure is illustrated at the processing step described with reference to FIG. 13A-13D. Referring to FIG. 30C, a horizontal cross-sectional view of a region of the second exemplary structure is illustrated at the processing step described with reference to FIG. 20A-20D. Generally, the second exemplary structure may be the same as the first exemplary structure up to the processing steps described with reference to FIG. 20A-20D.

According to an aspect of the present disclosure, the processing steps described with refence to FIG. 21A-21E are omitted during manufacture of the second exemplary structure. In the second exemplary structure, the sacrificial isolation opening fill structures 73 comprise a non-conductive material (e.g., an insulating material or an undoped semiconductor material, such as undoped amorphous silicon or polysilicon). The remaining second subset of the sacrificial isolation opening fill structures 73 after the processing steps of FIG. 20A-20D is herein referred to as non-conductive fill material pillars 73, which may have a different material composition than the support pillar structures 20. Thus, the lengthwise sidewalls of the lateral isolation trenches 79 comprise sidewall segments of the non-conductive fill material pillars 73.

Referring to FIG. 30D, the processing steps described with reference to FIG. 22A-22C and 23 can be performed to remove the second photoresist layer 29, and to form the laterally-extending cavities 43. Referring to FIG. 30E, the processing steps described with reference to FIG. 24 can be performed to form electrically conductive layers 46 in the laterally-extending cavities 43. Referring to FIG. 30F, the processing steps described with reference to FIG. 25A-29C may be performed.

The second exemplary structure is a semiconductor structure that comprises: alternating stacks (32, 46) of insulating layers 32 and electrically conductive layers 46, wherein each of the alternating stacks (32, 46) laterally extends along a first horizontal direction hd1, wherein the alternating stacks (32, 46) are laterally spaced apart from each other along a second horizontal direction hd2 by lateral isolation trench fill structures 76 that laterally extend along the first horizontal direction hd1; memory openings 49 vertically extending through a respective one of the alternating stacks (32, 46); and memory opening fill structures 58 located in a respective one of the memory openings 49, wherein the memory opening fill structures 58 are arranged in rows each laterally extending along the first horizontal direction hd1 with a memory opening 49 periodicity having a first pitch p1. Each of the lateral isolation trench fill structures 76 comprises a respective pair of lengthwise sidewalls, wherein each of the lengthwise sidewalls laterally extends generally along the first horizontal direction hd1 and comprises respective lateral undulations along a second horizontal direction hd2 that is perpendicular to the first horizontal direction hd1, the respective lateral undulations having an undulation periodicity that equals the first pitch p1. Geometrical centers of the memory opening fill structures 58 and centers of curvature of the lateral undulations of the lateral isolation trench fill structures 76 are located at lattice points LP of a two-dimensional periodic array in a horizontal cross-sectional view.

In one embodiment, the two-dimensional periodic array comprises a hexagonal array having a first periodicity direction along the first horizontal direction hd1. In one embodiment, each of the lateral isolation trench fill structures 76 comprises a single row, and not more than a single row, of lattice points LP arranged along the first horizontal direction hd1 within the two-dimensional periodic array in the horizontal cross-sectional view. In one embodiment, for each of the lengthwise sidewalls, the respective lateral undulations comprise a respective periodic one-dimensional array of horizontally-convex cylindrical surface segments. In one embodiment, the respective periodic one-dimensional array of horizontally-convex cylindrical surface segments is in direct contact with a respective periodic one-dimensional array of horizontally-concave cylindrical surface segments of electrically conductive layers 46 within a respective alternating stack (32, 46) among the alternating stacks (32, 46).

In one embodiment, the centers of curvature of the lateral undulations are located entirely outside the lateral isolation trench fill structures 76 in the horizontal cross-sectional view. In one embodiment, for each of the lengthwise sidewalls, the respective lateral undulations comprise a respective periodic one-dimensional array of horizontally-concave cylindrical surface segments.

In one embodiment, the three-dimensional memory device also comprises a one-dimensional arrays of non-conductive fill material pillars (which comprise the second subset (i.e., the peripheral rows) of the sacrificial isolation opening fill structures 73) in contact with the horizontally-concave cylindrical surface segments of the lengthwise sidewalls. The geometrical centers of the non-conductive fill material pillars 73 are located at additional at lattice points LP of the two-dimensional periodic array in the horizontal cross-sectional view. In one embodiment, the three-dimensional memory device also comprises outer blocking dielectric layers 44, wherein each of the outer blocking dielectric layers is in direct contact with a respective one of the electrically conductive layers 46, a respective subset of the memory opening fill structures 58, and a respective row of non-conductive fill material pillars 73 arranged along the first horizontal direction hd1.

In one embodiment, each of the lengthwise sidewalls of the lateral isolation trench fill structures 76 comprises a respective set of vertically-straight connecting surface segments that are interlaced with and adjoined to the respective lateral undulation. In one embodiment, the respective set of vertically-straight connecting surface segments comprise horizontally-convex surface segment having a radius of curvature that is greater than a difference between the first pitch p1 and a radius of a horizonal cross-sectional shape of each of the memory openings 49, and is less than a sum of the first pitch p1 and the radius of the horizonal cross-sectional shape of each of the memory openings 49.

In one embodiment, the second exemplary structure lateral isolation trench fill structures 76 that laterally extend along the first horizontal direction hd1. Each of the lateral isolation trench fill structures 76 comprises a respective pair of lengthwise sidewalls, wherein each of the lengthwise sidewalls laterally extends generally along the first horizontal direction hd1 and comprises respective lateral undulations along a second horizontal direction hd2 that is perpendicular to the first horizontal direction hd1, the respective lateral undulations having an undulation periodicity that equals the first pitch p1. The respective lateral undulations comprise vertically-straight and horizontally oval-arc-shaped surface segment in direct contact with vertically-straight and horizontally-concave surface segments of electrically conductive layers 46 of a respective alternating stack (32, 46). In one embodiment, each of the lengthwise sidewalls of the lateral isolation trench fill structures 76 comprises a respective set of vertically-straight connecting surface segments that are interlaced with, and adjoined to, the respective lateral undulation.

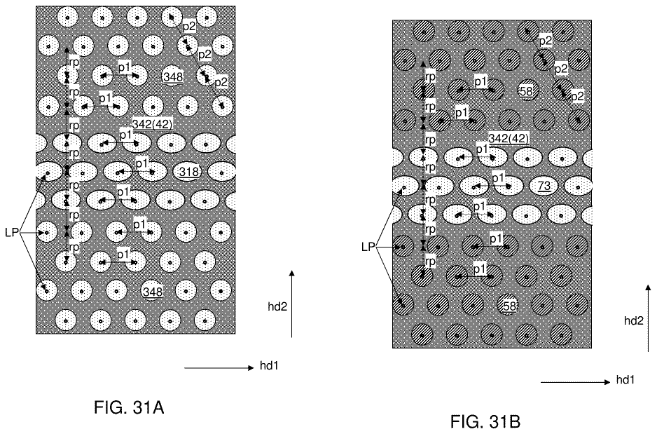

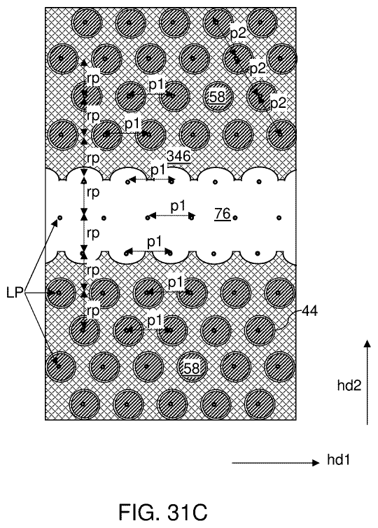

FIG. 31A-31C are various horizontal cross-sectional views of a third exemplary structure at a level of a third sacrificial material layer or a third electrically conductive layer 46 according to an embodiment of the present disclosure.

Referring to FIG. 31A, the third exemplary structure may be derived from the first exemplary structure or the second exemplary structure by employing elliptical or oval-shaped horizontal cross-sectional shapes for the isolation openings 77. In an illustrative example, the memory openings 49 may be formed with circular horizontal cross-sectional shapes, and the isolation openings 77 may be formed with horizontal cross-sectional shapes that are derived from a respective circle by elongation along the first horizontal direction hd1. FIG. 31A illustrates a region of the third exemplary structure after formation of the sacrificial third-tier opening fill structures (348, 368, 318, 378). Referring to FIG. 31B, the processing steps described with reference to the first exemplary structure can be performed to form memory opening fill structures 58 and the sacrificial isolation opening fill structures 73.

Referring to FIG. 31C, the processing steps described with reference to the first exemplary structure or the second exemplary structure can be performed to form lateral isolation trenches 79, electrically conductive layers 46, and lateral isolation trench fill structures 76. The lateral undulations of lengthwise sidewalls of the lateral isolation trench fill structures 76 may be laterally-convex or laterally-concave depending on presence or absence of non-conductive fill material pillars 73. In the third exemplary structure, the horizontal cross-sectional shapes of the lateral protrusions of the lengthwise sidewalls of the lateral isolation trench fill structures 76 may be arcs of ovals or ellipses, and thus, the radius of curvature for the lateral protrusions may not be definable.

The third exemplary structure comprises lateral isolation trench fill structures 76 that laterally extend along the first horizontal direction hd1. Each of the lateral isolation trench fill structures 76 comprises a respective pair of lengthwise sidewalls, wherein each of the lengthwise sidewalls laterally extends generally along the first horizontal direction hd1 and comprises respective lateral undulations along a second horizontal direction hd2 that is perpendicular to the first horizontal direction hd1, the respective lateral undulations having an undulation periodicity that equals the first pitch p1. The respective lateral undulations comprise vertically-straight and horizontally oval-arc-shaped surface segment in direct contact with vertically-straight and horizontally-concave surface segments of electrically conductive layers 46 of a respective alternating stack (32, 46). In one embodiment, each of the lengthwise sidewalls of the lateral isolation trench fill structures 76 comprises a respective set of vertically-straight connecting surface segments that are interlaced with and adjoined to the respective lateral undulation.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. All of the publications, patent applications and patents cited herein are incorporated herein by reference in their entirety.

What is claimed is:

1. A method of forming a semiconductor structure, comprising:
forming a vertically alternating sequence of continuous insulating layers and continuous sacrificial material layers;
forming memory openings and at least three adjacent rows of isolation openings though the vertically alternating sequence;
forming sacrificial isolation opening fill structures in the at least three rows of isolation openings;
forming memory opening fill structures in the memory openings, wherein each of the memory opening fill structures comprises a respective vertical stack of memory elements and a vertical semiconductor channel;
forming isolation cavities by removing a first subset of the sacrificial isolation opening fill structures from a middle row of the isolation openings without removing a second subset of the sacrificial isolation opening fill structures located in peripheral rows of the isolation openings;
forming laterally-undulating lateral isolation trenches through the vertically alternating sequence by performing at least one isotropic etch process that etches materials of the vertically alternating sequence around the first subset of isolation openings to divide the vertically alternating sequence into multiple alternating stacks of respective insulating layers and respective sacrificial material layers that are laterally spaced apart by the laterally-undulating lateral isolation trenches; and
replacing the sacrificial material layers in the multiple alternating stacks with electrically conductive layers.

2. The method of claim 1, wherein the at least one isotropic etch process etches the materials of the vertically alternating sequence selectively to a material of the second subset of the sacrificial isolation opening fill structures.

3. The method of claim 1, further comprising forming lateral isolation trench fill structures in the laterally-undulating lateral isolation trenches after the step of replacing the sacrificial material layers in the multiple alternating stacks with the electrically conductive layers, wherein the sacrificial material layers are replaced with the electrically conductive layers through the laterally-undulating lateral isolation trenches.

4. The method of claim 3, further comprising laterally expanding the laterally-undulating lateral isolation trenches by selectively removing the second subset of the sacrificial isolation opening fill structures located in peripheral rows of the isolation openings prior to the step of forming the lateral isolation trench fill structures.

5. The method of claim 4, wherein:
each lengthwise sidewall of the lateral isolation trenches comprises a respective row of lateral indentations defined by vertically-straight and horizontally-concave surface segments of the respective alternating stack, and a respective row of connecting surface segments of the respective alternating stack that are interlaced with the periodic repetition of vertically-straight and horizontally-concave surfaces of the respective alternating stack; and
each of the lateral isolation trench fill structures comprises a respective pair of lengthwise sidewalls, wherein each of the lengthwise sidewalls laterally extends generally along a first horizontal direction and comprises respective lateral undulations along a second horizontal direction perpendicular to the first horizontal direction.

6. The method of claim 3, wherein the laterally-undulating lateral isolation trenches are formed in contact with sidewalls of the second subset of the sacrificial isolation opening fill structures located in peripheral rows of the isolation openings.

7. The method of claim 1, wherein:
geometrical centers of the memory openings and isolation openings are formed at lattice points of a two-dimensional periodic array in a horizontal cross-sectional view; and
a direction of periodicity of the two-dimensional periodic array comprises a first horizontal direction.

8. The method of claim 7, wherein:
geometrical centers of the peripheral rows of the sacrificial isolation opening fill structures are located at most proximal lattice points from lattice points located at geometrical centers of the middle row of the sacrificial isolation opening fill structures in a horizontal cross-sectional view; and
the two-dimensional periodic array comprises a hexagonal array having a first periodicity direction along the first horizontal direction.

9. The method of claim 1, wherein the memory openings and the isolation openings have a circular horizontal cross-sectional shape.

10. The method of claim 1, wherein the memory openings have a circular horizontal cross-sectional shape, and the isolation openings have an oval horizontal cross-sectional shape

11. A semiconductor structure, comprising:
alternating stacks of insulating layers and electrically conductive layers, wherein each of the alternating stacks laterally extends along a first horizontal direction, wherein the alternating stacks are laterally spaced apart from each other along a second horizontal direction by lateral isolation trench fill structures that laterally extend along the first horizontal direction;
memory openings vertically extending through a respective one of the alternating stacks; and
memory opening fill structures each located in a respective one of the memory openings and comprising a respective vertical stack of memory elements located at levels of the electrically conductive layers and a respective vertical semiconductor channel, wherein the memory opening fill structures are arranged in rows each laterally extending along the first horizontal direction with a memory opening periodicity having a first pitch, wherein:
each of the lateral isolation trench fill structures comprises a respective pair of lengthwise sidewalls, wherein each of the lengthwise sidewalls laterally extends generally along the first horizontal direction and comprises respective lateral undulations along the second horizontal direction, the respective lateral undulations having an undulation periodicity that equals the first pitch; and
geometrical centers of the memory opening fill structures and centers of curvature of the lateral undulations of the lateral isolation trench fill structures are located at lattice points of a two-dimensional periodic array in a horizontal cross-sectional view.

12. The three-dimensional memory device of claim 11, wherein:
the two-dimensional periodic array comprises a hexagonal array having a first periodicity direction along the first horizontal direction; and
the alternating stacks comprise three or more alternating stacks, and all geometrical centers of the memory opening fill structures located within the three or more alternating stacks are located at a subset of the lattice points of the two-dimensional periodic array.

13. The three-dimensional memory device of claim 11, wherein:
each of the lateral isolation trench fill structure comprises three rows of lattice points arranged along the first horizontal direction within the two-dimensional periodic array in the horizontal cross-sectional view; and
wherein the centers of curvature of the lateral undulations are located entirely within the lateral isolation trench fill structures in the horizontal cross-sectional view.

14. The three-dimensional memory device of claim 13, wherein:
for each of the lengthwise sidewalls, the respective lateral undulations comprise a respective periodic one-dimensional array of horizontally-convex cylindrical surface segments; and
the respective periodic one-dimensional array of horizontally-convex cylindrical surface segments is in direct contact with a respective periodic one-dimensional array of horizontally-concave cylindrical surface segments of electrically conductive layers within a respective alternating stack of the alternating stacks.

15. The three-dimensional memory device of claim 11, wherein:
the centers of curvature of the lateral undulations are located entirely outside the lateral isolation trench fill structures in the horizontal cross-sectional view;
each of the lateral isolation trench fill structures comprises a single row of lattice points arranged along the first horizontal direction within the two-dimensional periodic array in the horizontal cross-sectional view; and
for each of the lengthwise sidewalls, the respective lateral undulations comprise a respective periodic one-dimensional array of horizontally-concave cylindrical surface segments.

16. The three-dimensional memory device of claim 15, further comprising a one-dimensional arrays of non-conductive fill-material pillars in contact with the horizontally-concave cylindrical surface segments of the lengthwise sidewalls, wherein geometrical centers of the non-conductive fill material pillars are located at additional at lattice points of the two-dimensional periodic array in the horizontal cross-sectional view.

17. The three-dimensional memory device of claim 16, further comprising outer blocking dielectric layers, wherein each of the outer blocking dielectric layers is in direct contact with a respective one of the electrically conductive layers, a respective subset of the memory opening fill structures, and a respective row of non-conductive fill-material pillars arranged along the first horizontal direction.

18. The three-dimensional memory device of claim 11, wherein:
each of the lengthwise sidewalls of the lateral isolation trench fill structures comprises a respective set of vertically-straight connecting surface segments that are interlaced with and adjoined to the respective lateral undulation; and
the respective set of vertically-straight connecting surface segments comprise horizontally-convex surface segment having a radius of curvature that is greater than a difference between the first pitch and a radius of a horizonal cross-sectional shape of each of the memory openings, and is less than a sum of the first pitch and the radius of the horizonal cross-sectional shape of each of the memory openings.

19. A semiconductor structure, comprising:
alternating stacks of insulating layers and electrically conductive layers, wherein each of the alternating stacks laterally extends along a first horizontal direction, wherein the alternating stacks are laterally spaced apart from each other along a second horizontal direction by lateral isolation trench fill structures that laterally extend along the first horizontal direction;
memory openings vertically extending through a respective one of the alternating stacks; and
memory opening fill structures each located in a respective one of the memory openings and comprising a respective vertical stack of memory elements located at levels of the electrically conductive layers and a respective vertical semiconductor channel, wherein the memory opening fill structures are arranged in rows each laterally extending along the first horizontal direction with a memory opening periodicity having a first pitch, wherein:
each of the lateral isolation trench fill structures comprises a respective pair of lengthwise sidewalls, wherein each of the lengthwise sidewalls laterally extends generally along the first horizontal direction and comprises respective lateral undulations along a second horizontal direction that is perpendicular to the first horizontal direction, the respective lateral undulations having an undulation periodicity that equals the first pitch; and
the respective lateral undulations comprise vertically-straight and horizontally oval-arc-shaped surface segment in direct contact with vertically-straight and horizontally-concave surface segments of electrically conductive layers of a respective alternating stack.

20. The semiconductor structure of claim 19, wherein each of the lengthwise sidewalls of the lateral isolation trench fill structures comprises a respective set of vertically-straight connecting surface segments that are interlaced with and adjoined to the respective lateral undulation.
